(19) United States
(12) Patent Application Publication
(10) Pub. No.: US 2025/0280540 A1
(43) Pub. Date: Sep. 4, 2025

(54) SEMICONDUCTOR DEVICE AND MANUFACTURING METHOD OF THE SEMICONDUCTOR DEVICE

(71) Applicant: SK hynix Inc., Icheon-si Gyeonggi-do (KR)

(72) Inventors: Young Geun JANG, Hwaseong-si Gyeonggi-do (KR); Wan Sup SHIN, Seongnam-si Gyeonggi-do (KR); Ki Hong LEE, Suwon-si Gyeonggi-do (KR); Jae Jung LEE, Seoul (KR)

(73) Assignee: SK hynix Inc., Icheon-si Gyeonggi-do (KR)

(21) Appl. No.: 19/213,044

(22) Filed: May 20, 2025

Related U.S. Application Data
(63) Continuation-in-part of application No. 18/076,151, filed on Dec. 6, 2022, now Pat. No. 12,336,179.
Application No. 18/076,151 is a continuation of application No. 17/549,456, filed on Dec. 13, 2021, now Pat. No. 11,925,021.
Application No. 17/549,456 is a continuation of application No. 16/387,218, filed on Apr. 17, 2019, now Pat. No. 11,233,063.

(30) Foreign Application Priority Data
Oct. 2, 2018 (KR) 10-2018-0117861

(51) Int. Cl. H10B 43/27; H01L 21/311; H01L 21/768; H01L 23/522; H10B 43/10; H10B 43/40; H10D 30/69; H10D 64/01

(52) U.S. Cl. CPC H10B 43/27; H01L 21/31144; H01L 21/76897; H01L 23/5226; H10B 43/10; H10B 43/40; H10D 30/694; H10D 64/037

(57) ABSTRACT

A semiconductor device includes a peripheral circuit structure, a memory cell array disposed over the peripheral circuit structure, and a bonding structure disposed between the peripheral circuit structure and the memory cell array. The memory cell array includes a first stack structure including first interlayer insulating layers and first conductive patterns disposed alternately with each other in a first direction over the bonding structure, second conductive patterns separated from each other in a horizontal direction between the first stack structure and the bonding structure, each of the second conductive patterns comprising electrode portions spaced apart from in the first direction and a connection portion extending in the first direction to couple the electrode portions, a vertical channel passing through the first stack structure and the electrode portions of each of the second conductive patterns, and a separation insulating layer disposed between the second conductive patterns.

### CROSS-REFERENCE TO RELATED APPLICATION

The present application is a continuation-in-part of U.S. patent application Ser. No. 18/076,151, filed on Dec. 6, 2022, which is a continuation application of U.S. patent application Ser. No. 17/549,456, filed on Dec. 13, 2021, which is a continuation application of U.S. patent application Ser. No. 16/387,218, filed on Apr. 17, 2019, which claims priority under 35 U.S.C. § 119(a) to Korean patent application number 10-2018-0117861, filed on Oct. 2, 2018, in the Korean Intellectual Property Office, the entire contents of which applications are incorporated herein by reference.

### BACKGROUND

### 1. Technical Field

Various embodiments generally relate to a semiconductor device and a method of manufacturing the semiconductor device, and more particularly, to a three-dimensional semiconductor memory device and a method of manufacturing the three-dimensional semiconductor device.

### 2. Related Art

A semiconductor device may include a memory cell array including a plurality of memory cells. The memory cell array may include the plurality of memory cells. The memory cells may be arranged in three dimensions on a substrate to improve integration density of the semiconductor device.

When manufacturing the memory cells arranged in three dimensions, various technologies for lowering a level of difficulty of a manufacturing process are being developed.

### SUMMARY

According to an embodiment, a semiconductor device may include a peripheral circuit structure, a memory cell array disposed over the peripheral circuit structure, and a bonding structure disposed between the peripheral circuit structure and the memory cell array. The memory cell array may include a first stack structure including first interlayer insulating layers and first conductive patterns disposed alternately with each other in a first direction over the bonding structure, second conductive patterns separated from each other in a horizontal direction between the first stack structure and the bonding structure, each of the second conductive patterns comprising electrode portions spaced apart from in the first direction and a connection portion extending in the first direction to couple the electrode portions, a vertical channel passing through the first stack structure and the electrode portions of each of the second conductive patterns, and a separation insulating layer disposed between the second conductive patterns.

According to an embodiment, a semiconductor device may include a peripheral circuit structure, a first sub-memory cell array disposed over the peripheral circuit structure, a second sub-memory cell array disposed over the first sub-memory cell array, a first bonding structure disposed between the peripheral circuit structure and the first sub-memory cell array, and a second bonding structure disposed between the first sub-memory cell array and the second sub-memory cell array. The first sub-memory cell array may include a first type-first stack structure including first type-first interlayer insulating layers and first type-first conductive patterns disposed alternately with each other in a first direction over the first bonding structure, first type-second conductive patterns separated from each other in a horizontal direction between the first type-first stack structure and the first bonding structure, each of the first type-second conductive patterns comprising first type-electrode portions spaced apart from in the first direction and a first type-connection portion extending in the first direction to couple the first type-electrode portions, a first type-vertical channel passing through the first type-first stack structure and the first type-electrode portions of each of the first type-second conductive patterns, and a first type-separation insulating layer disposed between the first type-second conductive patterns.

### BRIEF DESCRIPTION OF THE DRAWINGS

FIGS. 1A to 1D are block diagrams schematically illustrating semiconductor devices according to embodiments;

FIG. 2 is a cross-sectional diagram schematically illustrating a peripheral circuit structure;

FIGS. 3A and 3B are plan views illustrating a layout of a semiconductor device according to an embodiment;

FIGS. 4A and 4B are diagrams illustrating various cross sections of a semiconductor device according to embodiments;

FIGS. 4C, 4D, 4E, and 4F are diagrams illustrating various cross sections of a semiconductor device according to embodiments;

FIGS. 5 and 6 are diagrams illustrating an example of a variation of a first vertical structure and a second vertical structure;

FIGS. 7A and 7B are enlarged cross-sectional diagrams illustrating some regions of semiconductor devices according to embodiments;

FIGS. 8A and 8B are plan views illustrating examples of variations of a connecting portion according to an embodiment;

FIGS. 9A to 9D are cross-sectional diagrams illustrating various lower structures disposed under a first stack structure according to an embodiment;

FIG. 10 is a flowchart schematically illustrating a process of forming first stack structures penetrated by first channel structures and separated from each other by a first vertical structure;

FIGS. 11, 12A, 12B, 13A, 13B, and 14A to 14H are diagrams illustrating a manufacturing method of a semiconductor device according to an embodiment;

FIG. 15 is a cross-sectional diagram illustrating an example of a variation of a step of separating second conductive patterns from each other;

FIGS. 16A to 16C are cross-sectional diagrams illustrating a manufacturing method of a semiconductor device according to an embodiment;

FIG. 17 is a block diagram illustrating a configuration of a memory system according to an embodiment; and

FIG. 18 is a block diagram illustrating a configuration of a computing system according to an embodiment.

### DETAILED DESCRIPTION

The technical spirit of the present disclosure may include examples of embodiments to which various modifications and changes may be applied and which include various forms. Hereinafter, embodiments of the present disclosure will be described in order for those skilled in the art to which the present disclosure pertains to be able to readily implement the technical spirit of the present disclosure.

While terms such as “first” and “second” may be used to describe various components, such components must not be understood as being limited to the above terms. The above terminologies are used to distinguish one component from the other component, for example, a first component may be referred to as a second component without departing from a scope in accordance with the concept of the present disclosure and similarly, a second component may be referred to as a first component.

It will be understood that when an element is referred to as being “connected” or “coupled” to another element, it can be directly connected or coupled to the other element or intervening elements may also be present. In contrast, when an element is referred to as being “directly connected” or “directly coupled” to another element, no intervening elements are present. Meanwhile, other expressions describing relationships between components such as “ . . . between,” “immediately . . . between” or “adjacent to . . . ” and “directly adjacent to . . . ” may be construed similarly.

The terms used in the present application are merely used to describe particular embodiments, and are not intended to limit the present disclosure. Singular forms in the present disclosure are intended to include plural forms as well, unless the context clearly indicates otherwise. In the present specification, it should be understood that terms “include” or “have” indicate that a feature, a number, a step, an operation, a component, a part or the combination those of described in the specification is present, but do not exclude a possibility of presence or addition of one or more other features, numbers, steps, operations, components, parts or combinations thereof, in advance.

Various embodiments may be directed to a semiconductor device capable of lowering a level of difficulty of a manufacturing process of a semiconductor device and a manufacturing method of the semiconductor device.

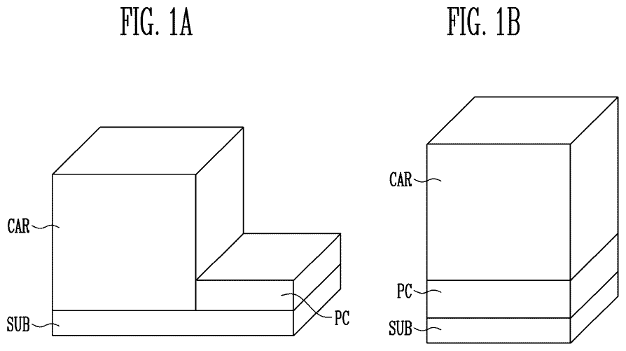

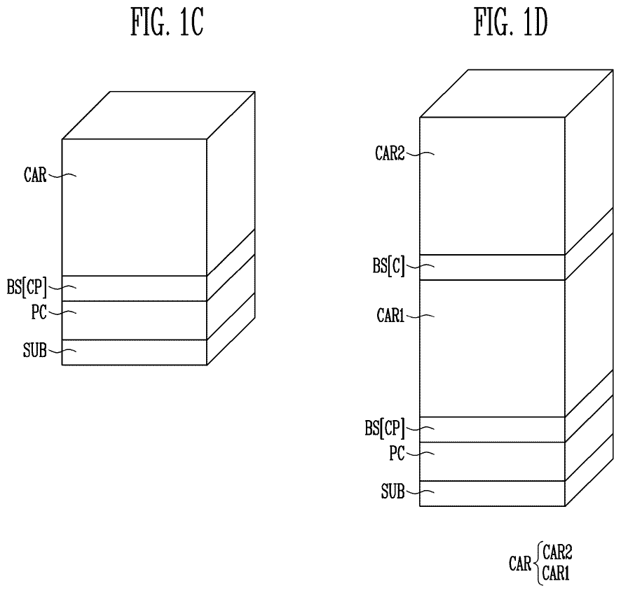

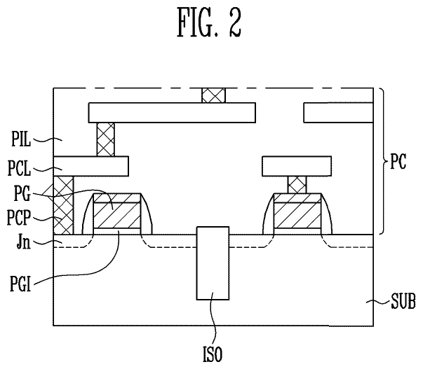

FIGS. 1A to 1D are block diagrams schematically illustrating semiconductor devices according to embodiments.

Referring to FIGS. 1A to 1D, each of semiconductor devices according to embodiments may include a peripheral circuit structure PC and a memory cell array CAR disposed above a substrate SUB.

The substrate SUB may be a single crystal semiconductor layer. For example, the substrate SUB may be a bulk silicon substrate, a silicon-on-insulator substrate, a germanium substrate, a germanium-on-insulator substrate, a silicon-germanium substrate, or an epitaxial thin film formed by a selective epitaxial growth method.

The memory cell array CAR may include a plurality of memory blocks. Each of the memory blocks may include a plurality of cell strings. Each of the cell strings may be electrically coupled to a bit line, a source line, word lines and select lines. Each of the cell strings may include memory cells and select transistors coupled in series. Each of the select lines may serve as a gate electrode of a corresponding select transistor, and each of the word lines may serve as a gate electrode of a corresponding memory cell.

The peripheral circuit structure PC may include NMOS transistors, PMOS transistors, a resistor, a capacitor, and interconnections which are electrically coupled to the memory cell array CAR. The NMOS and PMOS transistors, the resistor, and the capacitor may serve as devices which constitute a row decoder, a column decoder, a page buffer and a control circuit. The interconnections for electrical connections may include peripheral circuit wires and peripheral contact plugs.

As illustrated in FIG. 1A, the peripheral circuit structure PC may be disposed on a portion of the substrate SUB which is not overlapped with the memory cell array CAR.

Alternatively, as illustrated in FIGS. 1B to 1D, the peripheral circuit structure PC may be disposed between the memory cell array CAR and the substrate SUB. Because the peripheral circuit structure PC overlaps the memory cell array CAR, an area of the substrate SUB which is occupied by a region for the memory cell array CAR and a region for the peripheral circuit structure PC may be decreased.

In an embodiment, the memory cell array CAR shown in each of FIGS. 1A and 1B may formed over the substrate SUB after forming the peripheral circuit structure PC.

In an embodiment, the memory cell array CAR shown in FIG. 1C may be coupled to the peripheral circuit structure PC via a bonding structure BS[CP].

In an embodiment, the memory cell array CAR may include multiple sub-memory cell arrays coupled to each other via a bonding structure between neighboring sub-memory cell arrays. Referring to FIG. 1D, the memory cell array may CAR include a first sub-memory cell array CAR1 coupled to the peripheral circuit structure PC via a first bonding structure BS[CP] and a second sub-memory cell array CAR2 coupled to the first sub-memory cell array CAR1 via a second bonding structure BS[C].

FIG. 2 is a cross-sectional diagram schematically illustrating the peripheral circuit structure PC. The peripheral circuit structure PC shown in FIG. 2 may be included in the peripheral circuit structure PC shown in FIG. 1A, 1B, 1C, or 1D.

Referring to FIG. 2, the peripheral circuit structure PC may include peripheral gate electrodes PG, a peripheral gate insulating layer PGI, junctions Jn, peripheral circuit wires PCL, peripheral contact plugs PCP, and a peripheral circuit insulating layer PIL.

The peripheral gate electrodes PG may serve as gate electrodes of the NMOS transistor and the PMOS transistor of the peripheral circuit structure PC, respectively. The peripheral gate insulating layer PGI may be disposed between each of the peripheral gate electrodes PG and the substrate SUB.

The junctions Jn may be a region defined by injecting an n-type or p-type dopant into an active region of the substrate SUB. The junctions Jn may be disposed at both sides of each of the peripheral gate electrodes PG and serve as a source junction or a drain junction, respectively. The active region of the substrate SUB may be divided by an isolation layer ISO formed in the substrate SUB. The isolation layer ISO may include an insulating material.

The peripheral circuit wires PCL may be electrically coupled to a circuit of the peripheral circuit structure PC through the peripheral contact plugs PCP.

The peripheral circuit insulating layer PIL may cover the circuit of the peripheral circuit structure PC, the peripheral circuit wires PCL, and the peripheral contact plugs PCP. The peripheral circuit insulating layer PIL may include insulating layers stacked in multiple layers.

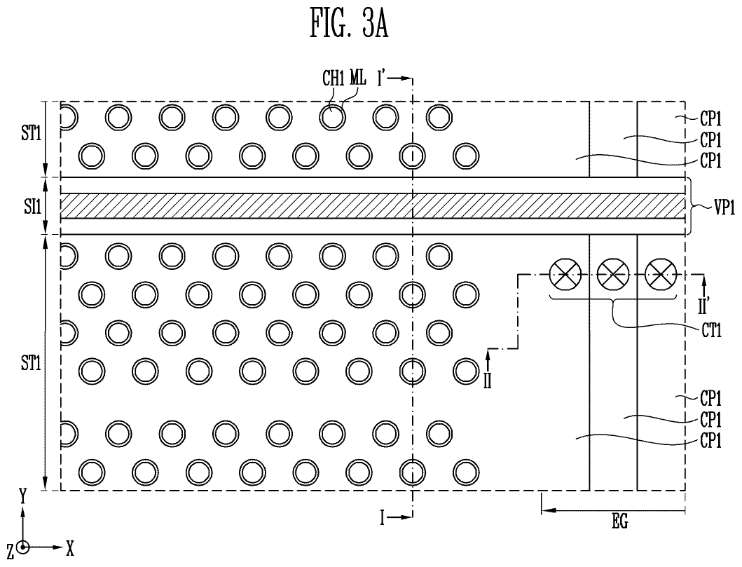

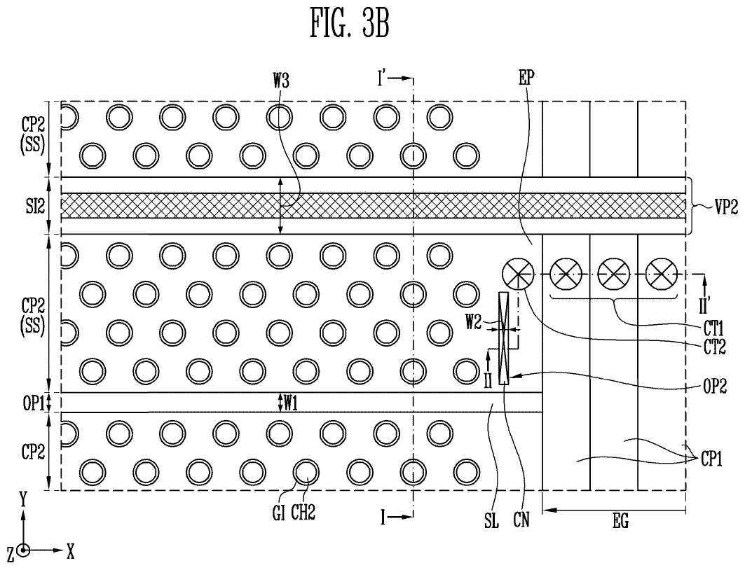

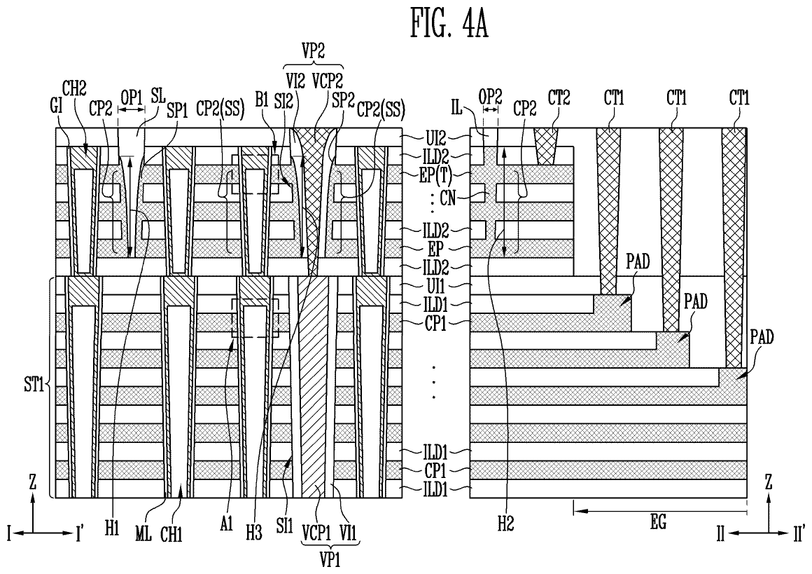

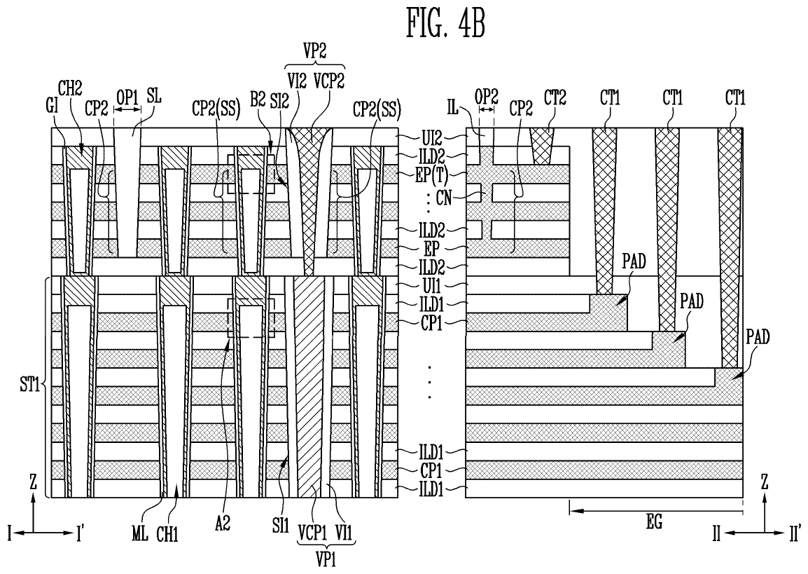

FIGS. 3A and 3B are plan views illustrating a layout of a semiconductor device according to an embodiment. For example, FIG. 3A is a plan view illustrating a layout of first conductive patterns CP1 and FIG. 3B is a plan view illustrating a layout of second conductive patterns CP2. Structures illustrated in FIGS. 3A and 3B, respectively, may be included in the memory cell array CAR shown in FIG. 1A, 1B, or 1C or may be included in each of the first and second sub-memory cell arrays CAR1 and CAR2 shown in FIG. 1D.

Referring to FIG. 3A, a semiconductor device according to an embodiment may include first stack structures ST1 separated from each other by a first slit SI1. Each of the first stack structures ST1 may include the first conductive patterns CP1 stacked to be spaced apart from each other in a first direction Z. An end portion EG of each of the first stack structures ST1 may include end portions of the first conductive patterns CP1 patterned into a stepped structure.

The first slit SI1 may extend a first horizontal direction X intersecting the first direction Z. The first slit SI1 may be filled with a first vertical structure VP1. The first stack structures ST1 may be arranged to be spaced apart from each other in a second horizontal direction Y. The first slit SI1 and the first vertical structure VP1 may be disposed between the first stack structures ST1 neighboring each other in the second horizontal direction Y. The second horizontal direction Y may intersect the first direction Z and the first horizontal direction X.

The first conductive patterns CP1 may be stacked in the first direction Z to form a stepped structure at the end portion EG of each of the first stack structures ST1. Each of the first conductive patterns CP1 may extend in the first horizontal direction X and the second horizontal direction Y. The first conductive patterns CP1 included in each of the first stack structures ST1 may extend to have different lengths from each other in the first horizontal direction X and may form a stepped structure. The end portions of the first conductive patterns CP1 may be exposed through the stepped structure.

The end portions of the first conductive patterns CP1 which are exposed through the stepped structure may be coupled to first contact plugs CT1. The first contact plugs CT1 may be disposed on the end portion EG of each of the first stack structures ST1. The first contact plugs CT1 may be arranged in a line in the first horizontal direction X at the end portion EG of each of the first stack structures ST1. However, the embodiments are not limited thereto. According to an embodiment, the first contact plugs CT1 may be arranged in a zigzag format at the end portion EG of each of the first stack structures ST1.

Each of the first stack structures ST1 may be penetrated by first channel structures CH1. The first channel structures CH1 may be surrounded with the first conductive patterns CP1. The first channel structures CH1 passing through each of the first stack structures ST1 may be arranged in a plurality of columns and a plurality of rows. The first channel structures CH1 may be disposed in a zigzag format. However, the embodiments are not limited thereto. According to an embodiment, the first channel structures CH1 may be arranged parallel with each other in the first horizontal direction X and the second horizontal direction Y. Multilayers ML may be disposed between the first channel structures CH1 and each of the first conductive patterns CP1. The multilayers ML correspond to the first channel structures CH1, respectively. Each multilayer ML may be disposed a corresponding first channel structure CH1 and each of the first conductive patterns CP1.

Referring to FIG. 3B, a semiconductor device according to an embodiment may include the second conductive patterns CP2. The second conductive patterns CP2 may be disposed on the first stack structures ST1 shown in FIG. 3A. Each of the second conductive patterns CP2 may expose the end portion EG of each of the first stack structures ST1 shown in FIG. 3A. In other words, the end portions of the first conductive patterns CP1 may extend farther in the first horizontal direction X than the second conductive patterns CP2.

A second slit SI2 may overlap the first slit SI1 shown in FIG. 3A. At least one first opening OP1 may overlap each of the first stack structures ST1 shown in FIG. 3A. The second slit SI2 may extend in the first horizontal direction X. The second slit SI2 may be filled with a second vertical structure VP2. The first opening OP1 may extend in the first horizontal direction X. The first opening OP1 may be filled with a separation insulating layer SL. The first opening OP1 and the separation insulating layer SL may have a linear shape extending in the first horizontal direction X. However, the embodiments are not limited thereto. According to an embodiment, the first opening OP1 and the separation insulating layer SL may have a wave shape or a zigzag format which extends in the first horizontal direction X.

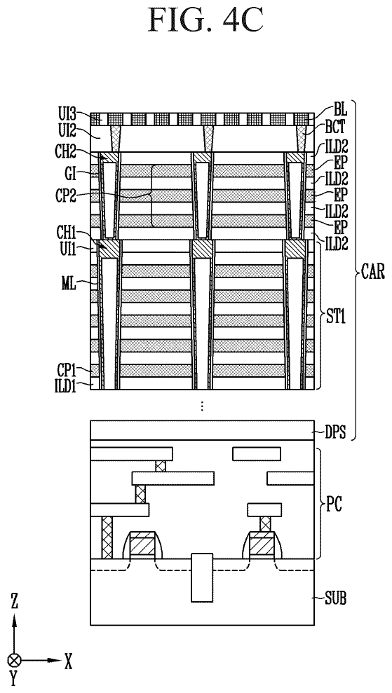

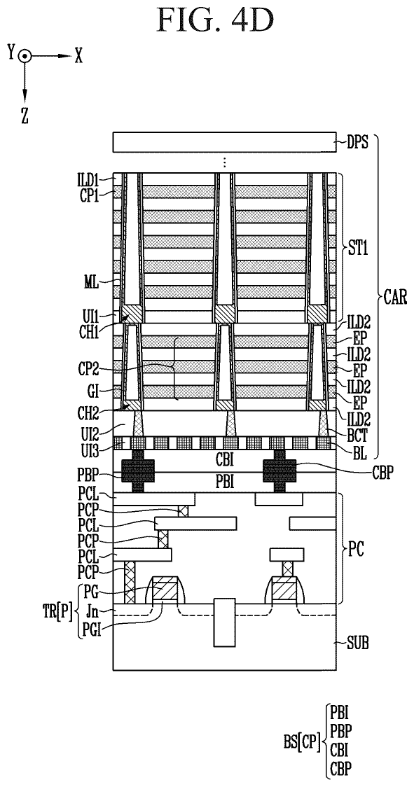

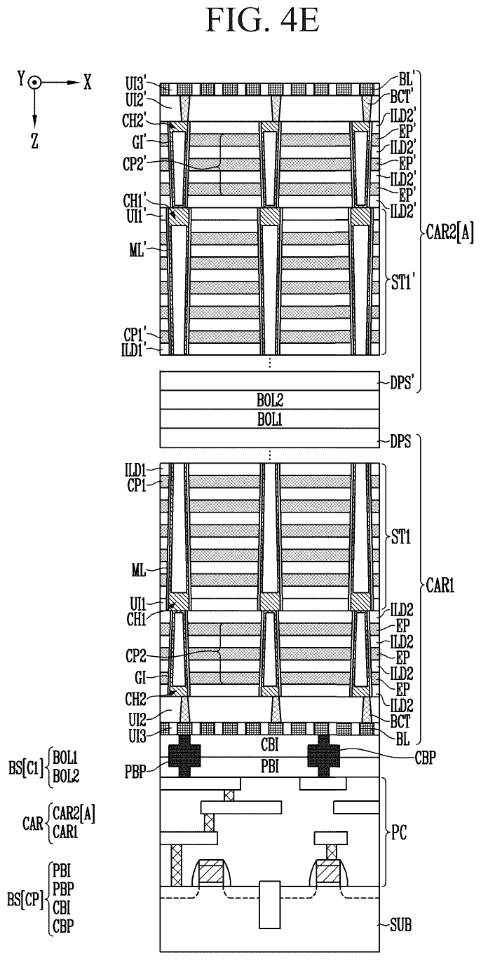

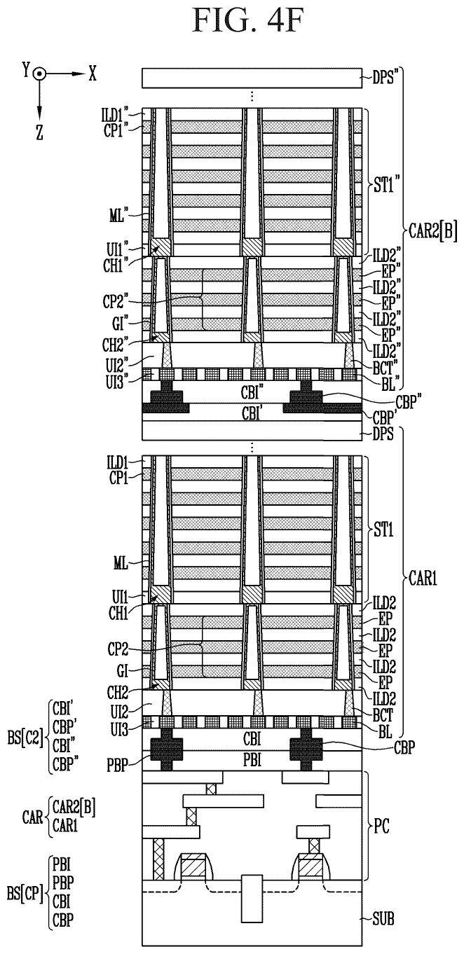

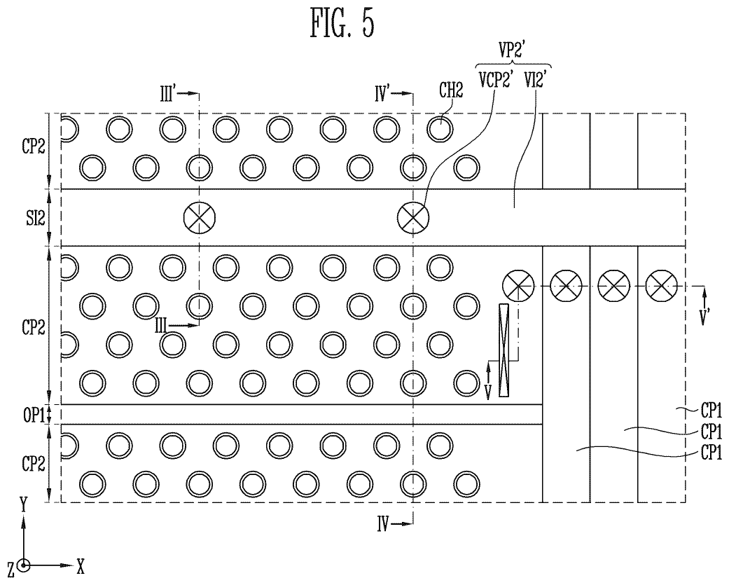

The second conductive patterns CP2 may be arranged to be spaced apart from each other in the second horizontal direction Y. The second conductive patterns CP2 may be separated from each other by the second slit SI2 or the separation insulating layer SL filling the first opening OP1. In an embodiment, a distance of the separation between the second conductive patterns CP2 adjacent to each other (i.e., caused by the second slit SI2 or the separation insulation layer SL filling the first opening OP1) may each be greater than a width of the connecting portion CN discussed with relation to FIGS. 4A and 4B below. The number of first openings OP1 overlapping each of the first stack structures ST1 shown in FIG. 3A may be variously set depending on the number of second conductive patterns CP2 separated from each other above each of the first stack structure ST1. The number of second conductive patterns CP2 disposed to be separated from each other above each of the first stack structures ST1 may be 2 or more.

The second conductive patterns CP2 may include a slit side pattern SS. The slit side pattern SS is one among the second conductive patterns CP2 and may be adjacent to the second slit SI2 and the second vertical structure VP2. Each of the second conductive patterns CP2 may fill a second opening OP2. Each of the second conductive patterns CP2 may be penetrated by second channel structures CH2.

The second channel structures CH2 may be coupled to the first channel structures CH1 shown in FIG. 3A, respectively. In an embodiment, the second channel structures CH2 may be coupled to the first channel structures CH1 in a one-to-one manner whereby a single first channel structure CH1 is coupled with a single overlapping second channel structure CH2. The first channel structure CH1 and the second channel structure CH2 coupled to each other may form a vertical channel. Each of the second conductive patterns CP2 may enclose at least one column of the second channel structures CH2. Each of the second conductive patterns CP2 may enclose the second channel structures CH2 disposed in a plurality of columns and a plurality of rows. The second channel structures CH2 may be disposed in a zigzag format. However, the embodiments are not limited thereto. According to an embodiment, the second channel structures CH2 may be arranged parallel with each other in the first horizontal direction X and the second horizontal direction Y. A gate insulating layer GI may be disposed between each of the second channel structures CH2 and each of the second conductive patterns CP2.

Each of the second conductive patterns CP2 may include electrode portions EP and a connecting portion CN. The electrode portions EP of each of the second conductive patterns CP2 may extend in the first horizontal direction X and the second horizontal direction Y, and may be stacked in the first direction Z. The connecting portion CN may fill the second opening OP2. The connecting portion CN may be surrounded with the electrode portions EP between the second channel structures CH2 and the first contact plugs CT1.

A first width W1 of the first opening OP1, a second width W2 of the second opening OP2, and a third width W3 of the second slit SI2 may be different from each other. Each of the first width W1, the second width W2, and the third width W3 may be measured in a transverse direction but not in a longitudinal direction and may be defined by a value measured on a horizontal plane. The first width W1 and the third width W3 may be measured in the second horizontal direction Y, and the second width W2 may be measured in the first horizontal direction X. A direction in which the second width W2 is measured may be variously changed according to a shape of the second opening OP2. The second width W2 may be smaller than the first width W1 (W2<W1). In other words, a width of the connecting portion CN may be smaller than a width between the second conductive patterns CP2 neighboring each other. The second width W2 may be smaller than the third width W3 (W2<W3). The first width W1 may be smaller than the third width W3 (W1<W3).

An end portion of each of the second conductive patterns CP2 may be coupled to a second contact plug CT2. The second contact plug CT2 and the first contact plugs CT1 may be arranged in a line in the first horizontal direction X. However, the embodiments are not limited thereto. According to an embodiment, the second contact plug CT2 and the first contact plugs CT1 may be arranged in a zigzag format.

FIGS. 4A and 4B are diagrams illustrating various cross sections of a semiconductor device according to an embodiment. For example, FIGS. 4A and 4B illustrate various cross sections taken along lines I-I′ and II-II′ shown in each of FIGS. 3A and 3B. Each of structures shown in FIGS. 4A and 4B may be included in the memory cell array CAR shown in FIG. 1A, 1B, or 1C or may be included in each of the first and second sub-memory cell arrays CAR1 and CAR2 shown in FIG. 1D.

Referring to FIGS. 4A and 4B, each of the first stack structures ST1 may include first interlayer insulating layers ILD1 disposed between the first conductive patterns CP1 neighboring in the first direction Z. In other words, each of the first stack structures ST1 may include the first interlayer insulating layers ILD1 and the first conductive patterns CP1 alternately stacked on each other in the first direction Z.

Each of the first conductive patterns CP1 may include at least one of a silicon layer, a metal silicide layer, a metal layer, and a metal nitride layer. Each of the first conductive patterns CP1 may include metal such as tungsten (W), cobalt (Co), and ruthenium (Ru) for low resistance wiring. A barrier pattern that prevents direct contact between the first interlayer insulating layers ILD1 and the first conductive patterns CP1 may be further formed.

The end portion of each of the first conductive patterns CP1 may include a pad portion PAD protruding in the first direction Z. Each of the first contact plugs CT1 may be coupled to the corresponding pad portion PAD. The first contact plugs CT1 may contact the end portions of the first conductive patterns CP1, and extend in the first direction Z. In an embodiment, the first contact plugs CT1 may be coupled to a pad portion PAD in a one-to-one manner whereby a single first contact plug CT1 is coupled with a single pad portion PAD. In an embodiment, the first contact plugs CT1 may be coupled to the first conductive patterns CP1 in a one-to-one manner whereby a single first contact plug CT1 is coupled with a single first conductive pattern CP1. In an embodiment, the first conductive patterns CP1 are stacked to form a stepped structure and the first contact plugs CT1 are coupled to end portions of the first conductive patterns CP1 which are exposed through the stepped structure in a one-to-one manner whereby a single first contact plug CT1 is coupled to an end portion of a single first conductive pattern CP1 which is exposed through the stepped structure.

The first interlayer insulating layers ILD1 may include various insulating materials. For example, the first interlayer insulating layers ILD1 may include a silicon oxide layer.

Each of the first stack structures ST1 may further include a first upper insulating layer UI1 covering the end portions of the first conductive patterns CP1. A surface of the first upper insulating layer UI1 may be flat. The first upper insulating layer UI1 may be a single layer or include multiple layers. According to an embodiment, the first upper insulating layer UI1 may include an oxide layer. According to an embodiment, the first upper insulating layer UI1 may include a stacked structure of an oxide layer and an etch stop layer. A nitride layer may serve as an etch stop layer.

Each of the first channel structures CH1 surrounded with the first interlayer insulating layers ILD1 and the first conductive patterns CP1 may extend in the first direction Z to pass through the first upper insulating layer UI1. The multilayers ML may be disposed between the first channel structures CH1 and the first conductive patterns CP1. Each of the multilayers ML may extend along an outer wall of the corresponding first channel structure CH1. However, the embodiments are not limited thereto. According to an embodiment, the multilayers ML may extend along interfaces between the first conductive patterns CP1 and the first interlayer insulating layers ILD1, and interfaces between the first channel structures CH1 and the first conductive patterns CP1.

The first vertical structure VP1 may include a first slit insulating layer VI1 and a first vertical conductive pattern VCP1. The first slit insulating layer VI1 may be formed on a sidewall of the first slit SI1 to cover a sidewall of each of the first stack structures ST1. The first vertical conductive pattern VCP1 may be formed on a sidewall of the first slit insulating layer VI1. The first vertical conductive pattern VCP1 may be insulated from the first conductive patterns CP1 by the first slit insulating layer VI1. The first slit insulating layer VI1 and the first vertical conductive pattern VCP1 may extend in the first direction Z. The first slit insulating layer VI1 and the first vertical conductive pattern VCP1 may be a linear shape extending in the first horizontal direction X as shown in FIG. 3A. The first slit insulating layer VI1 may include an oxide layer. The first vertical conductive pattern VCP1 may at least include a doped semiconductor layer. The doped semiconductor layer included in the first vertical conductive pattern VCP1 may include an n-type impurity. According to an embodiment, the first vertical conductive pattern VCP1 may include an n-type doped silicon layer.

The second conductive patterns CP2 separated from each other may be disposed above each of the first stack structures ST1. The second conductive patterns CP2 may include the slit side patterns SS disposed above different first stack structures ST1, neighboring each other, and separated from each other by the second slit SI2. The slit side patterns SS may be the second conductive patterns CP2 disposed adjacent to the first vertical structure VP1. The second conductive patterns CP2 disposed on the same first stack structure ST1 and neighboring each other may be separated from each other by the separation insulating layer SL filling the first opening OP1.

Each of the second conductive patterns CP2 may include the electrode portions EP stacked in the first direction Z and the connecting portion CN coupled in common to the electrode portions EP. The electrode portions EP and the connecting portion CN of each of the second conductive patterns CP2 may be integrated and may include the same conductive material. In an embodiment, each of the connecting portion CN may include a metal such as, but not limited to, at least one of tungsten (W), cobalt (Co), and ruthenium (Ru).

Each of the electrode portions EP may be disposed between second interlayer insulating layers ILD2 neighboring each other in the first direction Z. In other words, the electrode portions EP and the second interlayer insulating layers ILD2 may be alternately stacked on each other above the first stack structures ST1. The second interlayer insulating layers ILD2 may enclose the connecting portion CN. The electrode portions EP and the second interlayer insulating layers ILD2 may expose the end portion EG of each of the first stack structures ST1.

A stacked structure of the electrode portions EP and the second interlayer insulating layers ILD2 and the end portion EG of each of the first stack structures ST1 may be covered by a second upper insulating layer UI2. A surface of the second upper insulating layer UI2 may be flat. According to an embodiment, the second upper insulating layer UI2 may include an oxide layer.

The second slit SI2, the first opening OP1 and the second opening OP2 may pass through at least middle patterns among the second interlayer insulating layers ILD2. The middle patterns may be defined as the second interlayer insulating layers disposed between the electrode portions EP neighboring in the first direction Z. The second slit SI2, the first opening OP1, and the second opening OP2 may further pass through the second upper insulating layer UI2.

The first opening OP1 may be filled with the separation insulating layer SL. First spacer electrodes SP1 may be further formed on sidewalls of the second conductive patterns CP2 facing the separation insulating layer SL as shown in FIG. 4A. The first spacer electrodes SP1 may be omitted as shown in FIG. 4B. The first spacer electrodes SP1 may be included in each of the second conductive patterns CP2. The first spacer electrode SP1, the connecting portion CN, and the electrode portions EP of each of the second conductive patterns CP2 may be integrated with each other and may include the same conductive material. The first spacer electrodes SP1 may have a smaller height than the connecting portion CN (H1<H2). The first spacer electrodes SP1 may protrude farther in the first direction Z than the uppermost electrode portion T among the electrode portions EP. In an embodiment, first spacer electrodes SP1 may be formed on opposite side walls of a second conductive pattern CP2 and may be spaced apart from each other.

The separation insulating layer SL may completely fill a space between the second conductive patterns CP2 neighboring each other with the first opening OP1 interposed therebetween. For example, the separation insulating layer SL may completely fill a space between the first spacer electrodes SP1 neighboring each other as shown in FIG. 4A, or may completely fill the first opening OP1 as shown in FIG. 4B. The separation insulating layer SL may include an oxide layer. The first conductive patterns CP1 of each of the first stack structures ST1 may be coupled under the separation insulating layer SL and the first opening OP1.

The second opening OP2 may be filled with the connecting portion CN. The connecting portion CN may have a smaller height than the second opening OP2. An upper end of the second opening OP2 which is exposed by the connecting portion CN may be filled with an upper insulating pattern IL. The upper insulating pattern IL may include an oxide layer. The second opening OP2 and the connecting portion CN may extend in the first direction Z. The connecting portion CN may protrude farther in the first direction Z than the uppermost electrode portion T.

The second slit SI2 may overlap with the first slit SI1. The second slit SI2 may be filled with the second vertical structure VP2. Second spacer electrodes SP2 may be further formed on sidewalls of the second slit SI2 as shown in FIG. 4A. The second spacer electrodes SP2 may be omitted as shown in FIG. 4B. The second spacer electrodes SP2 may be included in each of the slit side patterns SS. The second spacer electrode SP2, the connecting portion CN, and the electrode portions EP of each of the slit side patterns SS may be integrated with each other and may include the same conductive material. The second spacer electrodes SP2 may have a smaller height than the connecting portion CN (H3<H2). The second spacer electrodes SP2 may protrude farther in the first direction Z than the uppermost electrode portion T. In an embodiment, second spacer electrodes SP2 may be formed on opposite side walls of a second conductive pattern CP2 and may be spaced apart from each other. The first spacer electrodes SP1 or the second spacer

electrodes SP2 which are formed on the sidewalls of the second conductive patterns CP2 facing each other may be spaced apart from each other as shown in FIG. 4A. The first spacer electrodes SP1 and the second spacer electrodes SP2 may extend along sidewalls of the corresponding second interlayer insulating layers ILD2, respectively.

Each of the second conductive patterns CP2 may include at least one of a silicon layer, a metal silicide layer, a metal layer, and a metal nitride layer. In an embodiment, each of the second conductive patterns CP2 may include metal for low resistance wiring. In an embodiment, each of the second conductive patterns CP2 may include a metal such as, but not limited to, at least one of tungsten (W), cobalt (Co), and ruthenium (Ru). A barrier pattern that prevents direct contact between the second interlayer insulating layers ILD2 and the second conductive patterns CP2 may be further formed.

The second interlayer insulating layers ILD2 may include various insulating materials. For example, the second interlayer insulating layers ILD2 may include a silicon oxide layer.

The second vertical structure VP2 may include a second slit insulating layer VI2 and a second vertical conductive pattern VCP2 which extend in the first direction Z. The second vertical conductive pattern VCP2 may extend towards the first vertical conductive pattern VCP1 to be coupled with the first vertical conductive pattern VCP1. The second slit insulating layer VI2 may be disposed between each of the slit side patterns SS and the second vertical conductive pattern VCP2. The second vertical conductive pattern VCP2 may be insulated from the slit side patterns SS by the second slit insulating layer VI2. The second slit insulating layer VI2 and the second vertical conductive pattern VCP2 may have a linear shape extending in the first horizontal direction X as shown in FIG. 3B. The second slit insulating layer VI2 may include an oxide layer. The second vertical conductive pattern VCP2 may include various conductive materials. For example, the second vertical conductive pattern VCP2 may include metal.

The second slit insulating layer VI2 may cover a sidewall of each of the second spacer electrodes SP2 as shown in FIG. 4A, or may cover sidewalls of the electrode portions EP and the second interlayer insulating layers ILD2 of each of the slit side patterns SS as shown in FIG. 4B.

The second contact plug CT2 may be coupled to the uppermost electrode portion T of each of the second conductive patterns CP2 and extend in the first direction Z.

The second channel structures CH2 surrounded with the second interlayer insulating layers ILD2 and the electrode portions EP may be covered by the second upper insulating layer UI2. The gate insulating layers GI may be disposed between the second channel structures CH2 and the electrode portions EP. Each of the gate insulating layers GI may extend along an outer wall of the second channel structure CH2.

The first contact plugs CT1 and the second contact plug CT2 may extend to pass through the second upper insulating layer UI2.

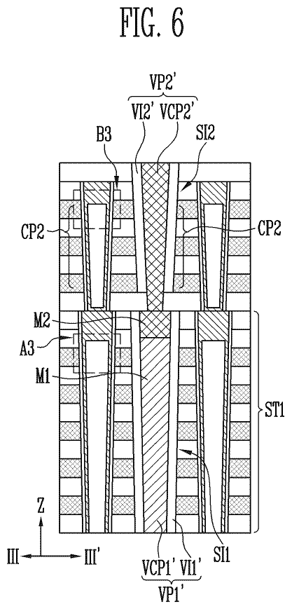

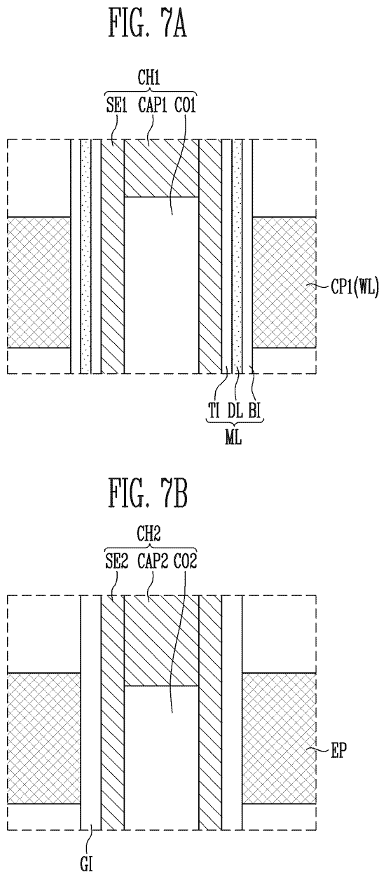

The first vertical structure VP1 and the second vertical structure VP2 may be variously changed. FIGS. 5 and 6 illustrate examples of variations of the first vertical structure VP1 and the second vertical structure VP2. Hereinafter, any repetitive descriptions of the same structure will be omitted.

FIGS. 4C, 4D, 4E, and 4F are diagrams illustrating various cross sections of a semiconductor device according to an embodiment. FIGS. 4C, 4D, 4E, and 4F illustrate various cross sections taken along a first horizontal direction X and a first direction Z shown in each of FIGS. 3A and 3B.

Referring to FIGS. 4C, 4D, 4E, and 4F, a semiconductor device may include a substrate SUB described with reference to FIGS. 1A and 1B, a peripheral circuit structure PC described with reference to FIG. 2, and a memory cell array CAR over the peripheral circuit structure PC.

Referring to FIGS. 4C and 4D, a memory cell array CAR may include a first stack structure ST1, a first channel structure CH1, a multilayer ML, second conductive patterns CP2, a second channel structure CH2, a gate insulating layer GI, a bit line contact BCT, a bit line BL, and a doped semiconductor structure DPS.

Referring to FIGS. 4C and 4D, the first stack structure ST1 may include first interlayer insulating layers ILD1 and first conductive patterns CP1 disposed alternately with each other in the first direction Z and a first upper insulating layer UI1, as described above with reference to FIGS. 4A and 4B. As shown in FIGS. 4A and 4B, a sidewall of the first stack structure ST1 in FIGS. 4C and 4D may be covered with a first slit insulating layer VI1 (refer to FIGS. 4A and 4B). The first channel structure CH1 may pass through the first stack structure ST1. The multilayer ML may be disposed between the first channel structure CH1 and each of the first conductive patterns CP1.

As shown in FIG. 3B, the second conductive patterns CP2 in FIGS. 4C and 4D may be separated from each other in the second horizontal direction Y. Referring to FIGS. 4C and 4D, each of the second conductive patterns CP2 may include electrode portions EP spaced apart from in the first direction Z and the electrode portions EP may be alternately stacked with second interlayer insulating layers ILD2 in the first direction Z. As shown in FIGS. 3B, 4A, and 4B, each of the second conductive patterns CP2 in FIGS. 4C and 4D may further include the connecting portion CN.

Referring to FIGS. 4C and 4D, the second channel structure CH2 may pass through the electrode portions EP and the second interlayer insulating layer ILD2, and the gate insulating layer GI may be disposed between the second channel structure CH2 and each of the electrode portions EP.

Referring to FIGS. 4C and 4D, the first channel structure CH1 and the second channel structure CH2 may connected to each other and form a vertical channel. As shown in FIGS. 3B, 4A, and 4B, the separation insulating layer SL may be disposed between the second conductive patterns CP2 in FIGS. 4C and 4D. As shown in FIGS. 4A and 4B, both the separation insulating layer SL and the connection portion CN may overlapped with the first stack structure ST1 in FIGS. 4C and 4D. As shown in FIGS. 4A and 4B, the second slit insulating layer VI2 may be disposed over the first slit insulating layer VI1 and one of the second conductive patterns CP2 in FIGS. 4C and 4D may be disposed between the second slit insulating layer VI2 and the separation insulating layer SL. As shown in FIG. 3B, the connection portion CN of one of the second conductive patterns CP2 in FIGS. 4C and 4D may be disposed between the second slit insulating layer VI2 and the separation insulating layer SL. In an embodiment, as shown in FIG. 4A, each of the second conductive patterns CP2 in FIGS. 4C and 4D may further include the spacer electrode SP connecting the electrode portions EP and extending along a sidewall of the separation insulating layer SL. In an embodiment, as shown in FIG. 4B, the electrode portions EP in FIGS. 4C and 4D may be in contact with the separation insulating layer SL.

Referring to FIGS. 4C and 4D, the semiconductor device may further include a second upper insulating layer UI2. The first stack structure ST1, the second conductive patterns CP2, the second upper insulating layer UI2 may be stacked in the first direction Z between the bit line BL and the doped semiconductor structure DPS. The bit line BL may be connected to the second channel structure CH2 via the bit line contact BCT passing through the second upper insulating layer UI2. The bit line BL may be formed inside a third upper insulating layer UI3 covering the second upper insulating layer UI2.

Referring to FIGS. 4C and 4D, one of the doped semiconductor structure DPS and the bit line BL is placed closer to the peripheral circuit structure PC than the other.

In an embodiment, as shown in FIG. 4C, the doped semiconductor structure DPS may be disposed between the first stack structure ST1 and the peripheral circuit structure PC. The memory cell array CAR including the doped semiconductor structure DPS in FIG. 4C may be formed above the peripheral circuit structure PC.

In an embodiment, as shown in FIG. 4D, the second conductive pattern CP2 and the bit line BL may be disposed between the first stack structure ST1 and the peripheral circuit structure PC, and the doped semiconductor structure DPS may be disposed over a surface of the first stack structure ST1 facing a direction opposite to a direction toward the bit line BL. In an embodiment, a bonding structure BS[CP] of the semiconductor device may include a peripheral circuit side bonding insulating structure PBI, a peripheral circuit side conductive bonding pattern PBP, a cell side bonding insulating structure CBI, and a cell side conducive bonding pattern CBP, which are disposed between the bit line BL of the memory cell array CAR and the peripheral circuit structure PC. In an embodiment, the first stack structure ST1 of the memory cell array CAR may be disposed over the bonding structure BS[CP] and the second conductive pattern CP2 is disposed between the first stack structure ST1 and the bonding structure BS[CP]. The peripheral circuit side bonding insulating structure PBI may be disposed between the peripheral circuit structure PC and the memory cell array CAR, the peripheral circuit side conductive bonding pattern PBP may be disposed inside the peripheral circuit side bonding insulating structure PBI, the cell side bonding insulating structure CBI may be disposed between the peripheral circuit side bonding insulating structure PBI and the memory cell array CAR, and the cell side conducive bonding pattern CBP may be disposed inside the cell side bonding insulating structure CBI. The cell side conducive bonding pattern CBP may be bonded to the peripheral circuit side conductive bonding pattern PBP. The memory cell array CAR may be electrically connected to the peripheral circuit structure PC via the cell side conducive bonding pattern CBP and the peripheral circuit side conductive bonding pattern PBP boned to each other. In an embodiment, a cell side conducive bonding pattern CBP connected to the bit line BL may be connected to a peripheral circuit side conductive bonding pattern PBP connected to a peripheral circuit wire PCL, which is connected to a transistor TR[P] included in a page buffer. According to this embodiment, the bit line BL of the memory cell array CAR may be electrically connected to the transistor TR[P] of the peripheral circuit structure PC via the cell side conducive bonding pattern CBP and the peripheral circuit side conductive bonding pattern PBP.

Referring to FIGS. 4E and 4F, a memory cell array CAR may include a first sub-memory cell array CAR1 and a second sub-memory cell array CAR2[A] or CAR2[B]. The first sub-memory cell array CAR1 may be disposed over the peripheral circuit structure PC and may be coupled to the peripheral circuit structure PC via a first bonding structure BS[CP]. The first bonding structure BS[CP] is disposed between the peripheral circuit structure PC and the first sub-memory cell array CAR1. The second sub-memory cell array CAR2[A] or CAR2[B] may be disposed over the first sub-memory cell array CAR1 and may be coupled to the first sub-memory cell array CAR1 via a second bonding structure BS[C1] or BS[C2]. The second bonding structure BS[C1] or BS[C2] is disposed between the first sub-memory cell array CAR1 and the second sub-memory cell array CAR2[A] or CAR2[B].

Referring to FIGS. 4E and 4F, the first sub-memory cell array CAR1 may include a first type-first stack structure ST1, a first type-first channel structure CH1, a first multilayer ML, first type-second conductive patterns CP2, a first type-second channel structure CH2, a first gate insulating layer GI, a first bit line contact BCT, a first bit line BL, and a first doped semiconductor structure DPS. As the first stack structure described above with reference to FIGS. 4C and 4D, the first type-first stack structure ST1 may include first type-first interlayer insulating layers ILD1 and first type-first conductive patterns CP1 disposed alternately with each other in the first direction Z over the first bonding structure BS[CP] and a first type-first upper insulating layer UI1.

The first type-first channel structure CH1 may pass through the first type-first stack structure ST1. The first multilayer ML may be disposed between the first type-first channel structure CH1 and each of the first type-first conductive patterns CP1. As the sidewall of the first stack structure ST1 is covered with the first slit insulating layer VI1 in FIGS. 4A and 4B, a sidewall of the first type-first stack structure ST1 may be covered with a first type-first slit insulating layer. The first bonding structure BS[CP] is placed closer to the first type-first upper insulating layer UI1 than the first doped semiconductor structure DPS.

The first type-second conductive patterns CP2 may be disposed between the first type-first stack structure ST1 and the first bonding structure BS[CP]. As the second conducive patterns CP2 are separated from each other by the separation insulating layer SL in FIGS. 3B, 4A, and 4B, the first type-second conductive patterns CP2 may be separated from each other in the second horizontal direction Y by a first type-separation insulating layer.

Each of the first type-second conductive patterns CP2 may include first type-electrode portions EP spaced apart from in the first direction Z. The first type-electrode portions EP may be alternately stacked with first type-second interlayer insulating layers ILD2 in the first direction Z. As the second conductive pattern CP2 further includes the connection portion CN connecting the electrode portions EP in FIGS. 3B, 4A, and 4B, the first type-second conductive pattern CP2 may further include a first type-connecting portion connecting the first type-electrode portions EP. The first type-second channel structure CH2 may pass through the first type-electrode portions EP and the first type-second interlayer insulating layer ILD2, and the first gate insulating layer GI may be disposed between the first type-second channel structure CH2 and each of the first type-electrode portions EP. The first type-first channel structure CH1 and the first type-second channel structure CH2 may connected to each other and form a first type-vertical channel. As one of the second conductive patterns CP2 is disposed between the second slit insulating layer VI2 and the separation insulating layer SL in FIGS. 3B, 4A, and 4B, the first type-second conductive pattern CP2 may be disposed between a first type-second slit insulating layer and the first type-separation insulating layer. In an embodiment, as the second conductive pattern CP2 further includes the spacer electrode SP adjacent to the separation insulating layer SL in FIG. 4A, the first type-second conductive pattern CP2 may further include a first type-spacer electrode connecting the first type-electrode portions and extending along a sidewall of the first type-separation insulating layer. In an embodiment, as the electrode portions EP is in contact with the separation insulating layer SL in FIG. 4B, the first type-electrode portions EP may be in contact with the first type-separation insulating layer.

Referring to FIGS. 4E and 4F, the semiconductor device may further include a first type-second upper insulating layer UI2 and a first type-third upper insulating layer UI3 between the first type-second conductive pattern CP2 and the first bonding structure BS[CP]. The first bit line BL may be connected to the second channel structure CH2 via the first bit line contact BCT passing through the first type-second upper insulating layer UI2. The first bit line BL may be formed inside the first type-third upper insulating layer UI3. The first doped semiconductor structure DPS may be disposed over a surface of the first type-first stack structure ST1 facing a direction opposite to a direction toward the first bit line BL.

Referring to FIGS. 4E and 4F, the first bonding structure BS[CP] of the semiconductor device may include a peripheral circuit side bonding insulating structure PBI, a peripheral circuit side conductive bonding pattern PBP, a cell side bonding insulating structure CBI, and a cell side conducive bonding pattern CBP as described above with reference to FIG. 4D.

Referring to FIGS. 4E and 4F, the second sub-memory cell array CAR2[A] or CAR2[B] may include a second type-first stack structure ST1′ or ST1″, a second type-first channel structure CH1′ or CH1″, a second multilayer ML′ or ML″, second type-second conductive patterns CP2′ or CP2″, a second type-second channel structure CH2′ or CH2″, a second gate insulating layer GI′ or GI″, a second bit line contact BCT′ or BCT″, a second bit line BL′ or BL″, and a second doped semiconductor structure DPS′ or DPS″. As the first stack structure described above with reference to FIGS. 4C and 4D, the second type-first stack structure ST1′ or ST1″ may include second type-first interlayer insulating layers ILD1′ or ILD1″ and second type-first conductive patterns CP1′ or CP1″ disposed alternately with each other in the first direction Z over the second bonding structure BS[C1] or BS[C2] and a second type-first upper insulating layer UI1′ or UI1″. The second type-first channel structure CH1′ or CH1″ may pass through the second type-first stack structure ST1′ or ST1″. The second multilayer ML′ or ML″ may be disposed between the second type-first channel structure CH1′ or CH1″ and each of the second type-first conductive patterns CP1′ or CP1″. As the sidewall of the first stack structure ST1 is covered with the first slit insulating layer VI1 in FIGS. 4A and 4B, a sidewall of the second type-first stack structure ST1′ or ST1″ may be covered with a second type-first slit insulating layer.

Referring to FIG. 4E, a second doped semiconductor structure DPS′ may be disposed over a second bonding structure BS[C1] and a second type-first stack structure ST1′ may be disposed between the second bonding structure BS[C1] and each of second type-second conductive patterns CP2′. The second bonding structure BS[C1] may include a first bonding layer BOL1 and a second bonding layer BOL2 bonded to each other between the first doped semiconductor structure DPS and the second doped semiconductor structure DPS′. Each of the first bonding layer BOL1 and the second bonding layer BOL2 may include at least one of a bonding metal and a bonding insulating layer. The bonding metal may include copper, etc. The bonding insulating layer may include a silicon oxide layer, etc.

Referring to FIG. 4E, a second type-second upper insulating layer UI2′, a second type-third upper insulating layer UI3′, a second bit line contact BCT′, and a second bit line BL′ may be arranged over a surface of each of the second type-second conductive patterns CP2′ facing a direction opposite to a direction toward the second type-first stack structure ST1′.

Referring to FIG. 4F, a second type-first stack structure ST1′ may be disposed over a second bonding structure BS[C2] and second type-second conductive patterns CP2′ may be disposed between the second type-first stack structure ST1′ and the second bonding structure BS[C2]. A second type-second upper insulating layer UI2″, a second type-third upper insulating layer UI3″, a second bit line contact BCT″, and a second bit line BL″ may be arranged between each of the second type-second conductive patterns CP2″ and the second bonding structure BS[C2].

Referring to FIG. 4F, the second bonding structure BS[C2] may include a first cell side bonding insulating structure CBI′, a first cell side conductive bonding pattern CBP′, a second cell side bonding insulating structure CBI″, and a second cell side conducive bonding pattern CBP″. The first cell side bonding insulating structure CBI′ may be disposed between the first sub-memory cell array CAR1 and the second sub-memory cell array CAR2[B], the first cell side conductive bonding pattern CBP′ may be disposed inside the first cell side bonding insulating structure CBI′, the second cell side bonding insulating structure CBI″ may be disposed between the first cell side bonding insulating structure CBI′ and the second sub-memory cell array CAR2[B], and the second cell side conducive bonding pattern CBP″ may be disposed inside the second cell side bonding insulating structure CBI″. In an embodiment, the second cell side conducive bonding pattern CBP″ may be connected to the second bit line BL″ and may be bonded to the first cell side conductive bonding pattern CBP′.

Referring to FIG. 4F, a doped second semiconductor structure DPS″ may be disposed over a surface of the second type-first stack structure ST1″ facing a direction opposite to a direction toward the second bit line BL″.

Referring to FIGS. 4E and 4F, each of the second type-second conductive patterns CP2′ or CP2″ may include second type-electrode portions EP' or EP″ spaced apart from in the first direction Z. The second type-electrode portions EP′ or EP″ may be alternately stacked with second type-second interlayer insulating layers ILD2′ or ILD2″ in the first direction Z. As the second conducive patterns CP2 are separated from each other by the separation insulating layer SL in FIGS. 3B, 4A, and 4B, the second type-second conductive patterns CP2′ or CP2″ may be separated from each other in the second horizontal direction Y by a second type-separation insulating layer. As the second conductive pattern CP2 further includes the connection portion CN connecting the electrode portions EP shown in FIGS. 3B, 4A and 4B, the second type-second conductive pattern CP2′ or CP2″ may further include a second type-connecting portion connection the second type-electrode portions EP. The second type-second channel structure CH2′ or CH2″ may pass through the second type-electrode portions EP′ or EP″ and the second type-second interlayer insulating layer ILD2′ or ILD2″ and the second gate insulating layer GI′ or GI″ may be disposed between the second type-second channel structure CH2′ or CH2″ and each of the second type-electrode portions EP′ or EP″. The second type-first channel structure CH1′ or CH1″ and the second type-second channel structure CH2′ or CH2″ may connected to each other and form a second type-vertical channel. As one of the second conductive patterns CP2 is disposed between the second slit insulating layer VI2 and 4B and the separation insulating layer SL in FIGS. 3B, 4A, and 4B, the second type-second conductive pattern CP2′ or CP2″ may is disposed between a second type-second slit insulating layer and the second type-separation insulating layer. As the second conductive pattern CP2 further includes the spacer electrode SP adjacent to the separation insulating layer SL in FIG. 4A, a second type-second conductive pattern CP2′ or CP2″ according to an embodiment may further include a second type-spacer electrode connecting the second type-electrode portions EP′ or EP″ and extending along a sidewall of the second type-separation insulating layer. As the electrode portions EP is in contact with the separation insulating layer SL in FIG. 4B, second type-electrode portions EP′ or EP″ according to an embodiment may be in contact with the second type-separation insulating layer.

Referring to FIGS. 4E and 4F, the second bit line BL′ or BL″ may be connected to the second type-second channel structure CH2′ or CH2″ via the second bit line contact BCT′ or BCT″ passing through the second type-second upper insulating layer UI2′ or UI2″. The second bit line BL′ or BL″ may be formed inside the second type-third upper insulating layer UI3′ or UI3″.

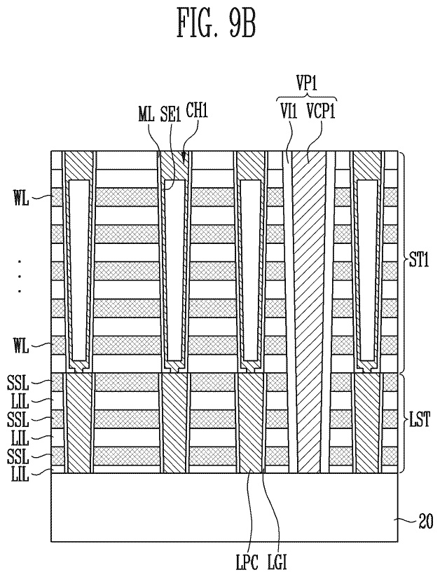

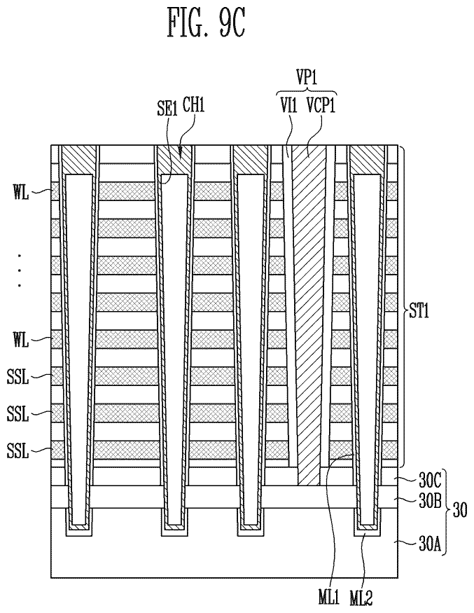

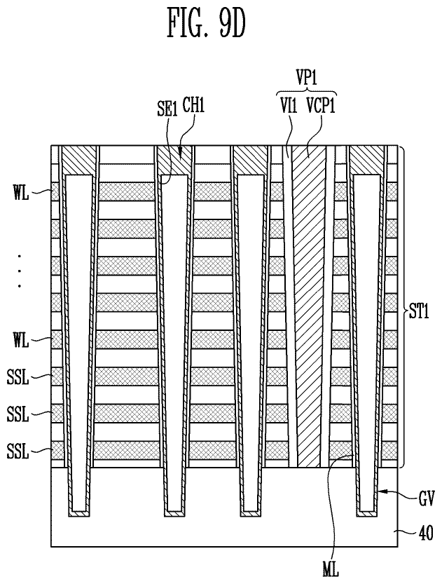

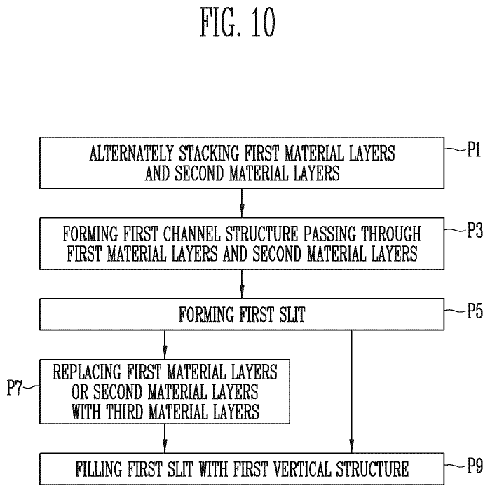

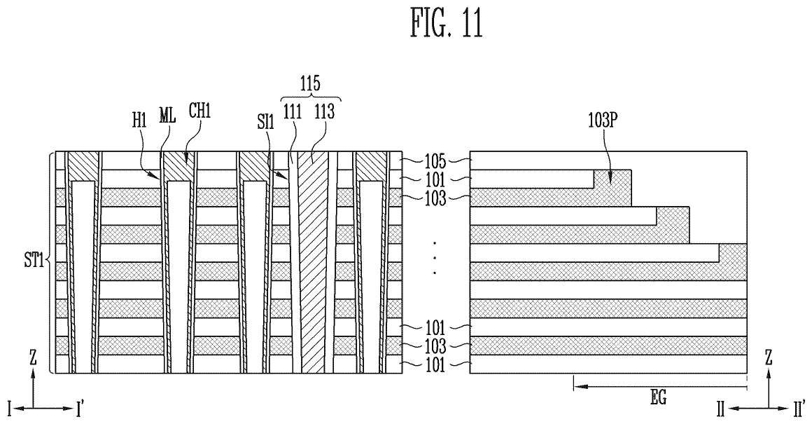

Each of the vertical channel, the first vertical channel, and the second vertical channel described above with reference to FIGS. 4C, 4D, 4E, and 4F may be connected to a corresponding doped semiconductor structure DPS, DPS′, or DPS″ in various ways. FIGS. 9A to 9D illustrate examples of various connections between each of the vertical channel, the first vertical channel, and the second vertical channel and the corresponding doped semiconductor structure.

FIG. 5 is a plan view illustrating a layout of a semiconductor device according to an embodiment. For example, FIG. 5 is a plan view illustrating a layout of the second conductive patterns CP2 penetrated by the second channel structures CH2. The layout of the second conductive patterns CP2 shown in FIG. 5 may applied to a layout of the first type-second conductive patterns CP2 describe above with reference to FIGS. 4E and FIGS. 4F and a layout of the second type-second conductive patterns CP2′ or CP2″ describe above with reference to FIGS. 4E and FIGS. 4F.

Referring to FIG. 5, as described above with reference to FIG. 3B, the second conductive patterns CP2 may be separated from each other by the second slit SI2 or the first opening OP1, and expose the end portions of the first conductive patterns CP1. According to an embodiment illustrated in FIG. 5, a second vertical structure VP2′ may include a second silt insulating layer VI2′ and second vertical conductive patterns VCP2′.

The second slit insulating layer VI2′ may fill the second slit SI2 and extend in the first horizontal direction X. The second slit insulating layer VI2′ may include an oxide layer. The second vertical conductive patterns VCP2′ may pass through the second slit insulating layer VI2′. The second vertical conductive patterns VCP2′ may be disposed to be spaced apart from each other in the first horizontal direction X. Each of the second vertical conductive patterns VCP2′ may include various conductive materials, for example, metal.

FIG. 6 is a cross-sectional diagram of a semiconductor device taken along line III-III′ shown in FIG. 5.

Referring to FIG. 6, the second slit SI2 may overlap the first slit SI1 separating the first stack structures ST1 from each other. The second vertical structure VP2′ may overlap a first vertical structure VP1′ disposed in the first slit SI1.

The first vertical structure VP1′ may include a first slit insulating layer VI1′ and a first vertical conductive pattern VCP1′. The first slit insulating layer VI1′ may be formed on a sidewall of a first slit SI1 to cover a sidewall of each of first stack structures ST1. The first vertical conductive pattern VCP1′ may be formed on a sidewall of the first silt insulating layer VI1′. According to an embodiment illustrated in FIG. 6, the first vertical conductive pattern VCP1′ may at least include a first conductive material M1 and a second conductive material M2. The first conductive material M1 may include a doped semiconductor layer. According to an embodiment, the first conductive material M1 may include an n-type impurity. According to an embodiment, the first conductive material M1 may include an n-type doped silicon layer. The second conductive material M2 may include metal. The first conductive material M1 and the second conductive material M2 may extend in the first horizontal direction X as shown in FIG. 3A. The first silt insulating layer VI1′ may include an oxide layer. Even when the second vertical conductive pattern VCP2′ does not extend in the first horizontal direction X, like the embodiments shown in FIG. 5, since the second conductive material M2 coupled to the second vertical conductive pattern VCP2′ includes metal, resistance of a vertical plug defined by coupling the first vertical conductive pattern VCP1′ and the second vertical conductive pattern VCP2′ may be decreased.

FIGS. 7A and 7B are enlarged cross-sectional diagrams illustrating some regions of semiconductor devices according to embodiments. For example, FIG. 7A is an enlarged diagram of regions A1 to A3 shown in FIGS. 4A, 4B, and 6, respectively. FIG. 7B is an enlarged diagram of regions B1 to B3 shown in FIGS. 4A, 4B, and 6, respectively.

Referring to FIG. 7A, the first channel structure CH1 may include a first semiconductor layer SE1. The first semiconductor layer SE1 may be conformally formed on an inner wall of the multilayer ML, or may completely fill a central region of the multilayer ML. According to an embodiment, the first semiconductor layer SE1 may include a silicon layer.

When the first semiconductor layer SE1 is conformally formed on the inner wall of the multilayer ML, the first channel structure CH1 may further include a first core insulating layer CO1 and a first capping pattern CAP1 which fill a central region of the first semiconductor layer SE1. The first core insulating layer CO1 may have a smaller height than the first semiconductor layer SE1. The first capping pattern CAP1 may be surrounded with an upper end of the first semiconductor layer SE1 which protrudes farther than the first core insulating layer CO1, and may be disposed on the first core insulating layer CO1. The first capping pattern CAP1 may contact the first semiconductor layer SE1. The first capping pattern CAP1 may include a doped semiconductor layer doped with an impurity. According to an embodiment, the first capping pattern CAP1 may include a doped silicon layer including an n-type impurity.

The multilayer ML may extend along a sidewall of the first channel structure CH1. The multilayer ML may include a tunnel insulating layer TI configured to enclose the first channel structure CH1, a data storage layer DL configured to enclose the tunnel insulating layer TI, and a blocking insulating layer BI configured to enclose the data storage layer DL.

The data storage layer DL may include a charge trapping layer, a material layer including a conductive nanodot, or a phase-change material layer.

The data storage layer DL may store data changed by using Fowler-Nordheim tunneling induced by the voltage difference between each of word lines WL among the first conductive patterns CP1 and the first channel structure CH1 which are described with reference to FIGS. 4A and 4B. The data storage layer DL may include a silicon nitride layer capable of trapping charges.

The data storage layer DL may store data based on an operating principal other than Fowler-Nordheim tunneling. For example, the data storage layer DL may include a phase-change material layer and may store data according to a phase change.

The blocking insulating layer BI may include an oxide layer capable of blocking charges. The tunnel insulating layer TI may include a silicon oxide layer capable of charge tunneling.

The first channel structure CH1 and the multilayer ML described above with reference to FIG. 7A may applied to the first channel structure CH1 and the multilayer ML describe above with reference to FIGS. 4C and FIGS. 4D, the first type-first channel structure CH1 and the first multilayer ML describe above with reference to FIGS. 4E and FIGS. 4F, and the second type-first channel structure CH1′ or CH1″ and the second multilayer ML′ or ML″ describe above with reference to FIGS. 4E and FIGS. 4F.

Referring to FIG. 7B, the second channel structure CH2 may include a second semiconductor layer SE2. The second semiconductor layer SE2 may be conformally formed on an inner wall of the gate insulating layer GI, or may completely fill a central region of the gate insulating layer GI. According to an embodiment, the second semiconductor layer SE2 may include a silicon layer.

When the second semiconductor layer SE2 is conformally formed on the inner wall of the gate insulating layer GI, the second channel structure CH2 may further include a second core insulating layer CO2 and a second capping pattern CAP2 which fill a central region of the second semiconductor layer SE2. The second semiconductor layer SE2 may extend along a sidewall and a bottom surface of the second core insulating layer CO2 and may contact the first channel structure CH1 as shown in FIGS. 4A, 4B, and 6. The second core insulating layer CO2 may have a smaller height than the second semiconductor layer SE2. The second capping pattern CAP2 may be surrounded with an upper portion of the second semiconductor layer SE2 which protrudes farther than the second core insulating layer CO2, and may be disposed on the second core insulating layer CO2. The second capping pattern CAP2 may contact the second semiconductor layer SE2. The second capping pattern CAP2 may include a doped semiconductor layer doped with an impurity. According to an embodiment, the second capping pattern CAP2 may include a doped silicon layer including an n-type impurity.

The gate insulating layer GI may be disposed between the second channel structure CH2 and the electrode portion EP of the second conductive pattern. The gate insulating layer GI may extend along the sidewall of the second channel structure CH2.

The second channel structure CH2 and the gate insulating layer GI described above with reference to FIG. 7B may applied to the second channel structure CH2 and the gate insulating layer GI describe above with reference to FIGS. 4C and FIGS. 4D, the first type-second channel structure CH2 and the first gate insulating layer GI describe above with reference to FIGS. 4E and FIGS. 4F and the second type-second channel structure CH2′ or CH2″, and the second gate insulating layer GI′ or GI″ describe above with reference to FIGS. 4E and FIGS. 4F.

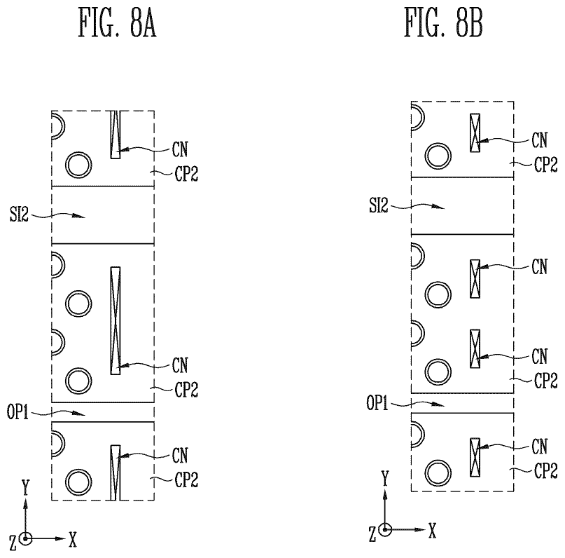

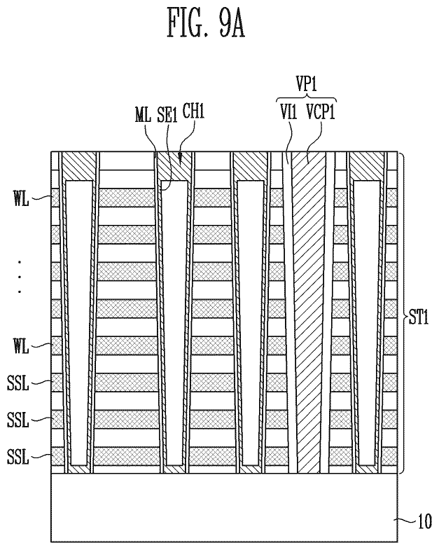

FIGS. 8A and 8B are plan views illustrating examples of variations of the connecting portion CN according to an embodiment. For example, each of FIGS. 8A and 8B is a plan view illustrating a layout of the second conductive patterns CP2.

Referring to FIGS. 8A and 8B, the second conductive patterns CP2 may be separated from each other by the second slit SI2 or the first opening OP1 as described above with reference to FIG. 3B.

Each of the second conductive patterns CP2 may include at least one connecting portion CN. According to an embodiment, the connecting portion CN may be coupled to the first opening OP1 and may have a bar shape extending in the second horizontal direction Y as shown in FIG. 3B. According to an embodiment, the connecting portion CN may be spaced apart from the first opening OP1 and may have a bar shape extending in the second horizontal direction Y as shown in FIG. 8A. According to an embodiment, two or more connecting portions CN included in each of the second conductive patterns CP2 may be arranged in a line in the second horizontal direction Y and may be spaced apart from each other as shown in FIG. 8B. A longitudinal section of each of the connecting portions CN may be variously designed such as in a polygon, a circle, or an ellipse.

FIGS. 9A to 9D are cross-sectional diagrams illustrating various lower structures disposed under a first stack structure according to an embodiment. The cross-sectional diagrams of the lower structure and the first stack structure shown in FIGS. 9A to 9D may correspond to the cross-sectional diagrams taken along line I-I′ shown in FIG. 3A.

Each of structures illustrated in FIGS. 9A to 9D, respectively, may be included in the memory cell array CAR shown in FIG. 1A, 1B, 1C or 1D. The first stack structure ST1 shown in each of FIGS. 9A to 9C may be the first stack structure ST1 described with reference to FIGS. 4A, 4B, 4C, and 4D. The first stack structure ST1 shown in each of FIGS. 9A to 9C may be the first type-first stack structure ST1 described with reference to FIGS. 4E and 4F. The first stack structure ST1 shown in each of FIGS. 9A to 9C may be the second type-first stack structure ST1′ or ST1″ described with reference to FIGS. 4E and 4F. The first vertical structure VP1 illustrated in each of FIGS. 9A to 9C may include the first slit insulating layer VI1 and the first vertical conductive pattern VCP1 which are described with reference to FIGS. 4A and 4B. The first vertical structure VP1 shown in each of FIGS. 9A to 9D may be replaced by the first vertical structure VP1′ described with reference to FIG. 6.

Referring to FIGS. 9A to 9D, a doped semiconductor structure 10, 20, 30, or 40 may be disposed under the first stack structure ST1. The doped semiconductor structure 10, 20, 30, or 40 may extend to be coupled to the first vertical conductive pattern VCP1. The doped semiconductor structure 10, 20, 30, or 40 may serve as a source region. The doped semiconductor structure 10, 20, 30, or 40 which serves as a source region may include a source dopant. For example, a source dopant may include an n-type impurity. The doped semiconductor structure 10, 20, or 40 may be a single layer as shown in FIGS. 9A, 9B, or 9D. The doped semiconductor structure 30 may include two or more layers 30A, 30B, and 30C sequentially stacked on each other as shown in FIG. 9C.

According to an embodiment, the doped semiconductor structures 10, 20, and 30A shown in FIGS. 9A to 9C, respectively, may be formed by injecting an impurity into a surface of the substrate SUB shown in FIG. 1A, or by depositing at least one doped silicon layer over the substrate SUB. According to an embodiment, the doped semiconductor structures 10, 20, and 30A to 30C shown in FIGS. 9A to 9C, respectively, may be formed by forming an insulating layer over the substrate SUB shown in FIG. 1B, and depositing at least one doped silicon layer over the insulating layer. According to an embodiment, the doped semiconductor structure 40 shown in FIG. 9D may be formed by depositing at least one doped silicon layer after bonding the cell side conductive bonding structure CBP to the peripheral side conductive bonding structure PBP as shown in FIG. 4D and FIG. 4E. According to an embodiment, the doped semiconductor structure 40 shown in FIG. 9D may be formed by depositing at least one doped silicon layer after bonding the second cell side conductive bonding structure CBP″ to the first cell side conductive bonding structure CBP′ as shown in FIG. 4F. Before forming of the doped semiconductor structure 40, a portion of the multilayer ML may be removed to expose an end of the first channel structure CH1. The exposed end of the first channel structure CH1 may protrude further than the first stack structure ST1 and the doped semiconductor structure 40 may include a groove GV into which the end of the first channel structure CH1 is inserted.

Referring to FIGS. 9A, 9C, and 9D, the first conductive patterns of the first stack structure ST1 may serve as the word lines WL or at least one of source select lines SSL. At least the lowermost pattern among the first conductive patterns may serve as the source select line SSL. However, the embodiments are not limited thereto, and one or more first conductive patterns sequentially disposed on the lowermost pattern may serve as the source select lines SSL. The first conductive patterns disposed on at least one of the source select lines SSL may serve as the word lines.

Referring to FIG. 9B, the first conductive patterns of the first stack structure ST1 may serve as the word lines WL. A lower stack structure LST may be further formed between the first stack structure ST1 and the doped semiconductor structure 20. The lower stack structure LST may include at least one lower interlayer insulating layer LIL and at least one source select line SSL which are alternately stacked on each other.

Referring to FIGS. 9A to 9D, the first semiconductor layer SE1 of each of the first channel structures CH1 may be coupled to the doped semiconductor structure 10, 20, 30, or 40.

A bottom surface of the first semiconductor layer SE1 may directly contact the doped semiconductor structure 10 as shown in FIG. 9A. The multilayer ML enclosing each of the first channel structures CH1 may be penetrated by the first semiconductor layer SE1.

The bottom surface of the first semiconductor layer SE1 may be coupled to a lower channel structure LPC passing through the lower stack structure LST as shown in FIG. 9B. The multilayer ML enclosing each of the first channel structures CH1 may be penetrated by the first semiconductor layer SE1.

An outer wall of the lower channel structure LPC may be surrounded with a lower gate insulating layer LGI. The doped semiconductor structure 20 may contact a bottom surface of the lower channel structure LPC. The first semiconductor layer SE1 may be coupled to the doped semiconductor structure 20 via the lower channel structure LPC. The lower channel structure LPC may be formed by growing a semiconductor material by a selective epitaxial growth method or by depositing a semiconductor material. The lower channel structure LPC may include an n-type impurity. The impurity may be doped into the lower channel structure LPC by an in-situ method or an ion injection method.

The first channel structures CH1 may extend into the doped semiconductor structure 30 as shown in FIG. 9C. The doped semiconductor structure 30 may include the first to third layers 30A, 30B, and 30C which are sequentially stacked on each other. Each of the first to third layers 30A, 30B, and 30C may include a doped semiconductor layer. According to an embodiment, each of the first to third layers 30A, 30B, and 30C may include a doped silicon layer.

The first channel structures CH1 may extend into the first layer 30A. The first semiconductor layer SE1 of each of the first channel structures CH1 may directly contact the second layer 30B. The second layer 30B may protrude towards a sidewall of the first semiconductor layer SE1 and may divide the multilayer into a first multilayer pattern ML1 and a second multilayer pattern ML2. The third layer 30C may be omitted in some cases.

The end of the first channel structure CH1 may be in contact with a surface of the doped semiconductor structure 40 adjacent to the groove GV as shown in FIG. 9D.

Referring to FIGS. 9A to 9D, the first vertical conductive pattern VCP1 may extend to contact the doped semiconductor structure 10, 20, 30, or 40. The first vertical conductive pattern VCP1 may extend to pass through the lower stack structure LST and to contact the doped semiconductor structure 20 as shown in FIG. 9B. The first slit insulating layer VI1 may extend to cover a sidewall of the lower stack structure LST. The first vertical conductive pattern VCP1 may extend into the doped semiconductor structure 30 as shown in FIG. 9C. The third layer 30C and the second layer 30B may be penetrated by the first vertical conductive pattern VCP1.

The first vertical conductive pattern VCP1 may serve as a pick-up plug for transferring an electrical signal to the doped semiconductor structure 10, 20, 30, or 40.

According to the structures described above with reference to FIGS. 9A to 9D, memory cells may be formed at intersections of the first channel structures CH1 and the word lines WL, and a source select transistor may be formed at an intersection of each of the first channel structures CH1 and the source select line SSL shown in FIGS. 9A, 9D, and 9D, or at an intersection of the lower channel structure LPC and the source select line SSL shown in FIG. 9B.

The second conductive patterns CP2 shown in FIGS. 3B, 4A, and 4B may be formed on the structures shown in FIGS. 9A to 9D. The second conductive patterns CP2 may serve as a drain select line. A drain select transistor may be formed at an intersection of each of the second conductive patterns CP2 which serves as the drain select line and each of the second channel structures CH2.

According to a manufacturing method of a semiconductor device according to an embodiment, a process of forming first conductive patterns enclosing first channel structures is separately performed from a process of forming second conductive patterns enclosing second channel structures. Thereby, a level of difficulty of a manufacturing process of a semiconductor device may be decreased. Hereinafter, various embodiments of a manufacturing method of a semiconductor device will be described below.

FIG. 10 is a flowchart schematically illustrating a process of forming first stack structures penetrated by first channel structures and separated from each other by a first vertical structure.

Referring to FIG. 10, step P1 for alternately stacking first material layers and second material layers may be performed. The first material layers may include a different material from the second material layers.

According to an embodiment, the first material layers may include an insulating material for a first interlayer insulating layer, and the second material layers may include a sacrificial material having a different etch rate from the first material layers. The first material layers may include a silicon oxide layer and the second material layers may include a silicon nitride layer.

According to an embodiment, second material layers may include a conductive material for first conductive patterns, and first material layers may include a sacrificial material having a different etch rate from the second material layers. The first material layers may include an undoped silicon layer and the second material layers may include a doped silicon layer.

According to an embodiment, first material layers may include an insulating material for a first interlayer insulating layer, and second material layers may include a conductive material for first conductive patterns. The first material layers may include a silicon oxide layer and the second material layers may include one of a doped silicon layer, a metal silicide layer, a metal layer, and a metal nitride layer.

After step P1, step P3 for forming a first channel structure passing through the first material layers and the second material layers may be performed. Step P3 may include forming first holes passing through the first material layers and the second material layers, and filling each of the first holes with the first channel structure.

Step P5 for forming a first slit may be performed following step P3. After step P5, steps P7 and P9 may be sequentially performed or step P9 may be performed while skipping step P7 depending on embodiments.

According to an embodiment, when first material layers include an insulating material for a first interlayer insulating layer, and second material layers include a sacrificial material, the second material layers may be replaced with third material layers through first slits during step P7. For example, the second material layers may be selectively removed by bringing an etching material in through a first slit. Damage to the first material layers may be minimized by using a difference in etch rate between the first material layers and the second material layers. Subsequently, regions from which the second material layers are removed may be filled with the third material layers. The third material layers may be a conductive material for first conductive patterns.

According to an embodiment, when second material layers include a conductive material for first conductive patterns and first material layers include a sacrificial material having a different etch rate from the second material layers, the first material layers may be replaced with third material layers through a first slit during step P7. For example, the first material layers may be selectively removed by bringing an etching material in through the first slit. Damage to the second material layers may be minimized by using a difference in etch rate between the first material layers and the second material layers. Subsequently, regions from which the first material layers are removed may be filled with the third material layers. The third material layers may be an insulating material for an interlayer insulating layer.

According to an embodiment, step P7 may be omitted when first material layers include an insulating material for a first interlayer insulating layer and second material layers include a conductive material for first conductive patterns.

According to various embodiments as described above, after first stack structures each including first interlayer insulating layers and first conductive patterns alternately stacked on each other are formed, a first slit may be filled with a first vertical structure during step P9.

FIGS. 11, 12A, 12B, 13A, 13B, and 14A to 14H are diagrams illustrating a manufacturing method of a semiconductor device according to an embodiment.

FIG. 11 shows cross-sectional diagrams illustrating an embodiment of a first stack structure formed by the process illustrated in FIG. 10.

Referring to FIG. 11, the first stack structures ST1 penetrated by the first channel structures CH1 may be formed by using a series of processes illustrated in FIG. 10. Each of the first stack structures ST1 may include first interlayer insulating layers 101 and first conductive patterns 103 which are alternately stacked on each other, and may be penetrated by the first channel structures CH1. The first conductive patterns 103 may be stacked to form a stepped shape at the end portion EG of each of the first stack structures ST1.

As described above, to form the first conductive patterns 103 to have the stepped shape, a process for pattering the first material layers and the second material layers which are described above with reference to FIG. 10 into a stepped shape may be further performed. The process for patterning the first material layers and the second material layers into the stepped shape may be performed between steps P1 and P5 which are illustrated in FIG. 10.

Each of the first conductive patterns 103 may include a pad portion 103P protruding from the end portion EG of each of the first stack structures ST1 in the first direction Z. According to an embodiment, a process for directly forming a conductive pattern on an end portion of each of the second material layers which are patterned into the stepped shape may be further performed to form the pad portion 103P. According to an embodiment, a process for forming a pad pattern on an end portion of each of the second material layers which are patterned into the stepped shape may be further performed to form the pad portion 103P. The pad pattern may include the same material as the second material layers. The pad pattern may be replaced with the third material layers during a step, i.e., P7 of FIG. 10, in which the second material layers are replaced with the third material layers for the first conductive patterns 103.

Each of the first stack structures ST1 may further include a first upper insulating layer 105 covering the stepped structure. A surface of the first upper insulating layer 105 may be planarized by a planarizing process.

The first channel structures CH1 may be formed in first holes H1 during step P3 described above with reference to FIG. 10. Step P3 described above with reference to FIG. 10 may further include forming the multilayer ML on a surface of each of the first holes before forming the first channel structures CH1. The first channel structures CH1 may be formed on the multilayer ML. Each of the first channel structures CH1 and the multilayer ML may have the structure described above with reference to FIG. 7A. The first channel structures CH1, the first holes H1, and the multilayer ML may extend to pass through the first upper insulating layer 105.

The first slit SI1 separating the first stack structures ST1 from each other may extend to pass through the first upper insulating layer 105. The first slit SI1 may be filled with a first vertical structure 115 during step P9 illustrated in FIG. 10. Step P9 may include forming a first slit insulating layer 111 and forming a first vertical conductive pattern 113.

According to an embodiment, forming the first slit insulating layer 111 may include conformally forming an insulating layer on the sidewall of the first slit SI1. According to an embodiment, forming the first slit insulating layer 111 may include completely filling the first slit SI1 with an insulating material, and etching the insulating material to expose a bottom surface of the first slit SI1.

The first vertical conductive pattern 113 may at least include a doped semiconductor layer. According to an embodiment, the first vertical conductive pattern 113 may include a doped silicon layer. When the first vertical conductive pattern 113 serves as a source pick-up plug coupled to a source region, the first vertical conductive pattern 113 may include an n-type impurity. According to an embodiment, the first vertical conductive pattern 113 may include the first conductive material M1 and the second conductive material M2 as shown in FIG. 6.

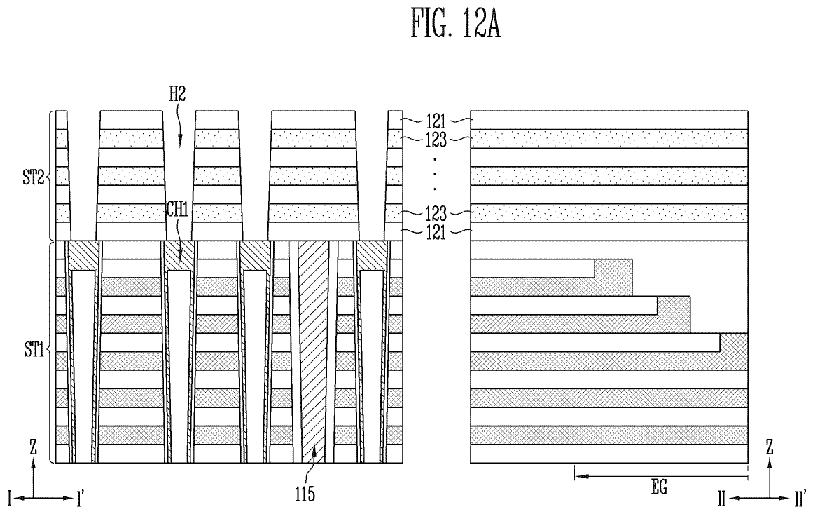

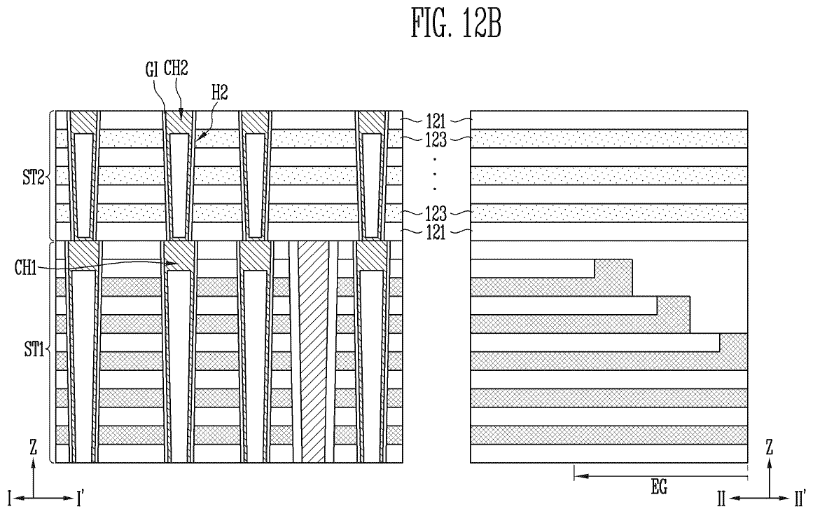

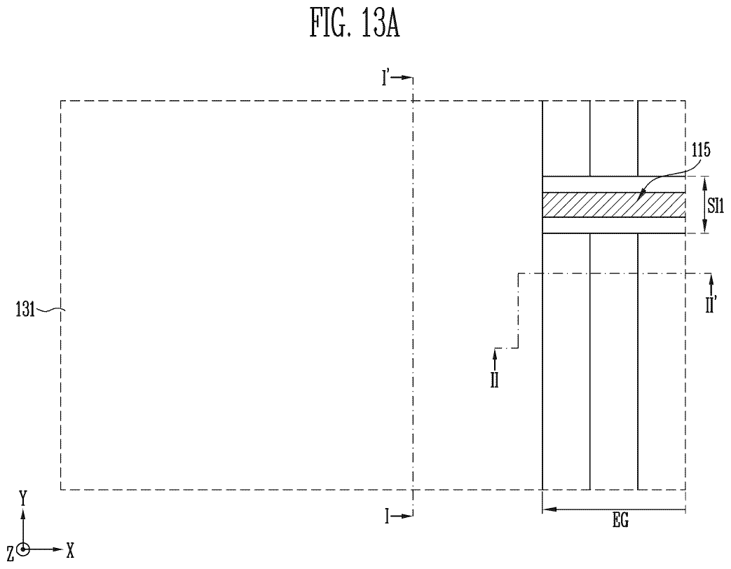

FIGS. 12A and 12B are cross-sectional diagrams illustrating a process of forming a second stack structure penetrated by second channel structures.

Referring to FIG. 12A, a second stack structure ST2 extending to cover the first vertical structure 115 and the end portion EG of each of the first stack structures ST1 may be formed on the first stack structures ST1. The second stack structure ST2 may be formed by alternately stacking second interlayer insulating layers 121 and sacrificial layers 123 in the first direction Z.

The second interlayer insulating layers 121 may include various insulating materials. According to embodiment, the second interlayer insulating layers 121 may include a silicon oxide layer. The sacrificial layers 123 may include a different material from the second interlayer insulating layers 121. For example, the sacrificial layers 123 may include a material having a different etch rate from the second interlayer insulating layers 121.

According to an embodiment, the sacrificial layers 123 may include a silicon nitride layer.

After forming the second stack structure ST2, second holes H2 passing through the second interlayer insulating layers 121 and the sacrificial layers 123 of the second stack structure

ST2 may be formed. The second holes H2 may expose the first channel structures CH1, respectively. In an embodiment, the second holes H2 may expose the first channel structures CH1 in a one-to-one manner whereby a single second hole H2 exposes a single first channel structure CH1.

Referring to FIG. 12B, the second channel structures CH2 may be formed in the second holes H2, respectively. In an embodiment, the second channel structures CH2 may be formed in the second holes H2 in a one-to-one manner whereby a single second channel structure CH2 is formed in a single second hole H2. The second channel structures CH2 may be coupled to the first channel structures CH1, respectively. In an embodiment, the second channel structures CH2 may be coupled to the first channel structures CH1 in a one-to-one manner whereby a single second channel structure CH2 is coupled to a single first channel structure CH1. The gate insulating layer GI may be formed on a sidewall of each of the second holes H2 before forming the second channel structures CH2. Each of the second channel structures CH2 may be formed on the gate insulating layer GI. Each of the second channel structures CH2 and the gate insulating layer GI may have the structure described above with reference to FIG. 7B.

The second interlayer insulating layers 121 and the sacrificial layers 123 which enclose the second channel structures CH2 coupled to the first channel structures CH1 and are alternately stacked on each other may be formed by the processes described with reference to FIGS. 12A and 12B.

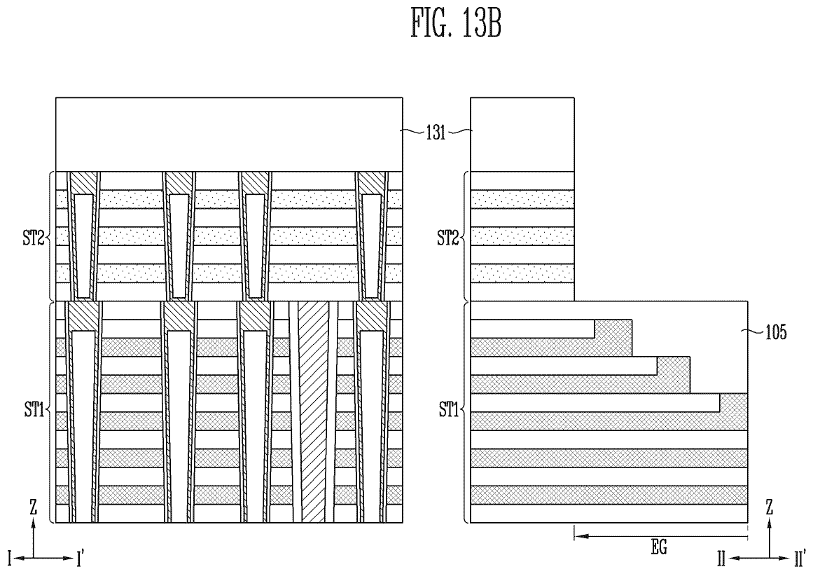

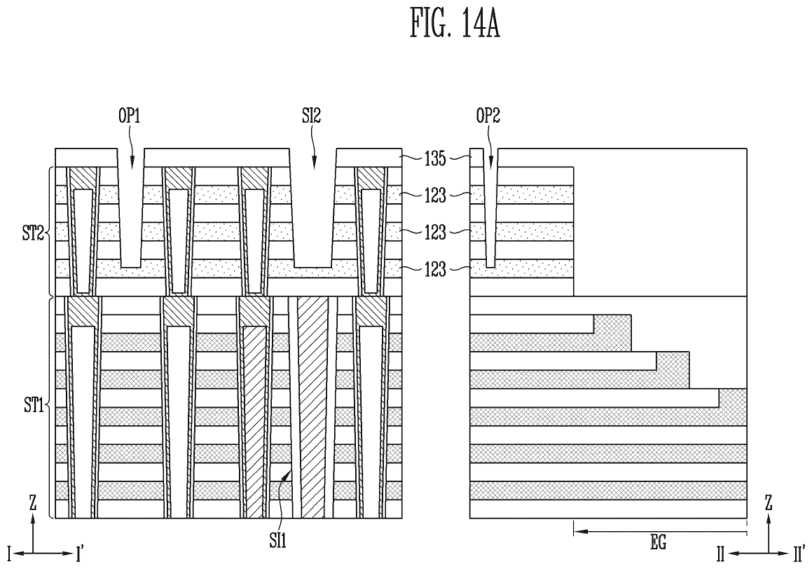

FIGS. 13A and 13B are a plan view and a cross-sectional diagram, respectively, which illustrate a process of exposing an end portion of each of first stack structures.

Referring to FIGS. 13A and 13B, a mask pattern 131 exposing the end portion EG of each of the first stack structures ST1 may be formed on the second stack structure ST2. The mask pattern 131 may be a photoresist pattern.

Thereafter, the second stack structure ST2 may be etched by an etching process using the mask pattern 131 as an etching barrier. Thereby, the end portion EG of each of the first stack structures ST1 may be exposed. For example, the first upper insulating layer 105 corresponding to the end portion EG of each of the first stack structures ST1 may be exposed. A portion of the first slit SI1 and a portion of the first vertical structure VP1 may be exposed by the etched second stack structure ST2.

The mask pattern 131 may be removed after the end portion EG of each of the first stack structures ST1 is exposed.

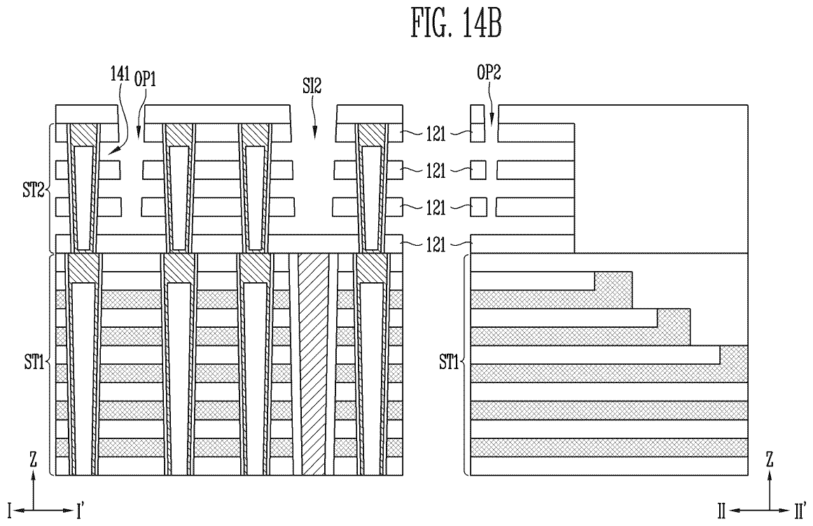

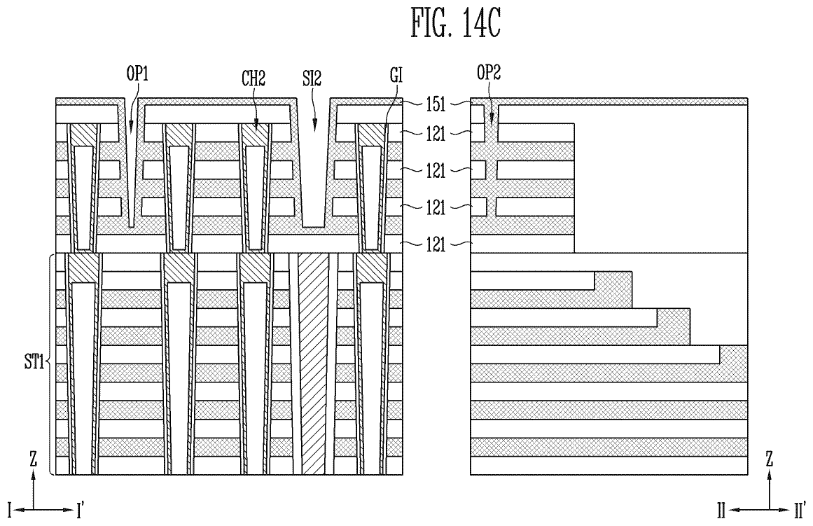

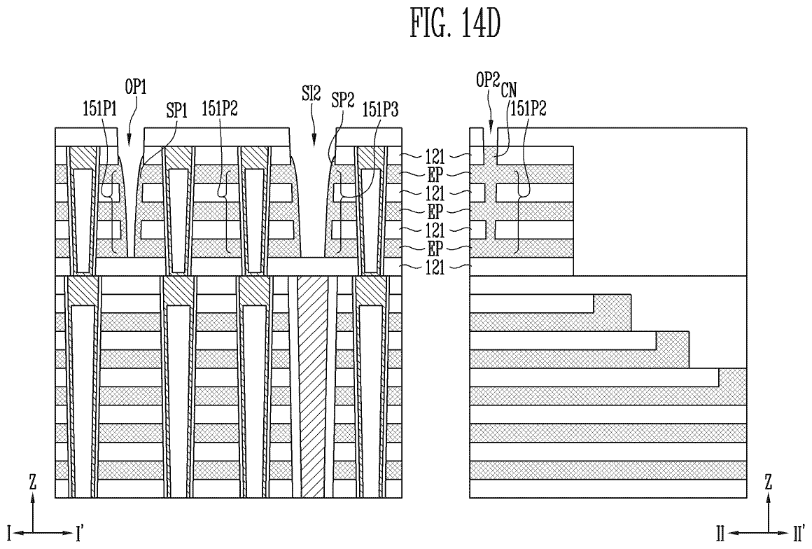

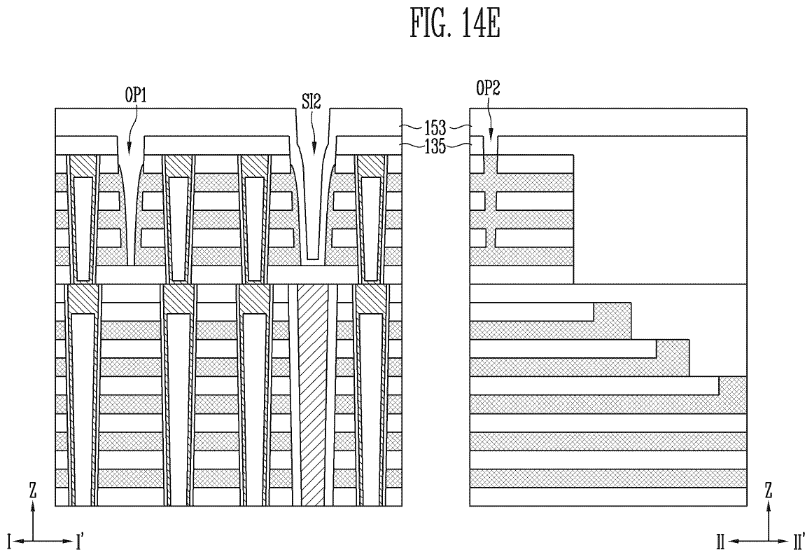

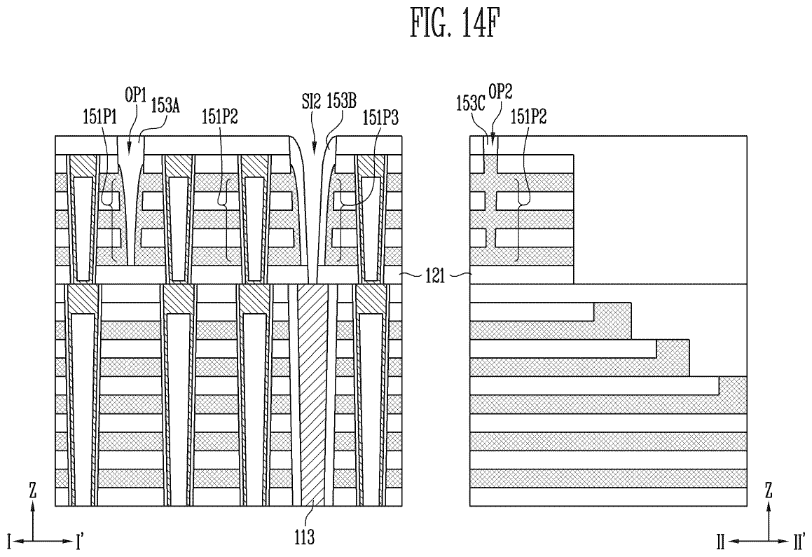

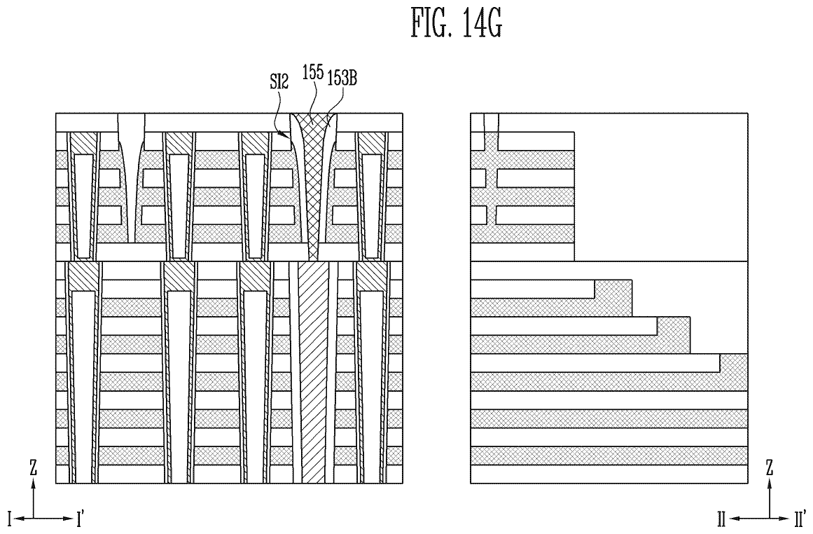

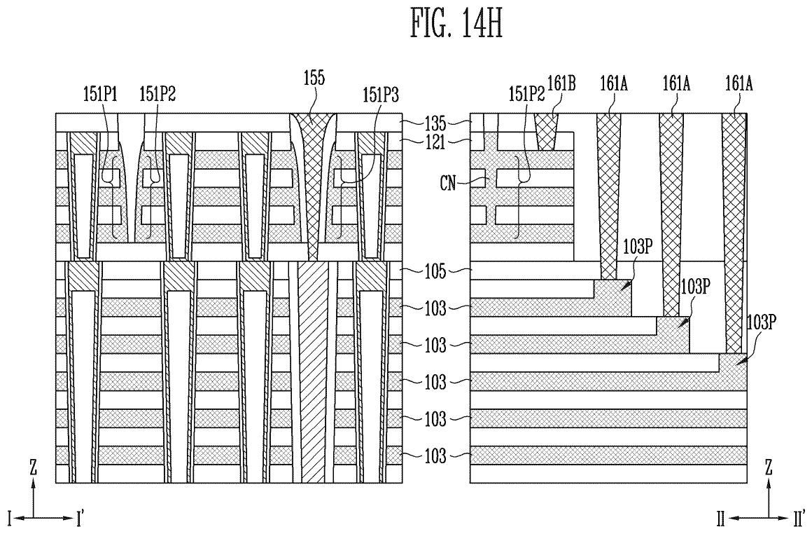

FIGS. 14A to 14H are cross-sectional diagrams illustrating subsequent processes after the mask pattern is removed.

Referring to FIG. 14A, a second upper insulating layer 135 covering the end portion EG of each of the first stack structures ST1 which is exposed by the second stack structure ST2 may be formed on the second stack structure ST2. The second upper insulating layer 135 may include various insulating materials. For example, the second upper insulating layer 135 may include an oxide layer. A surface of the second upper insulating layer 135 may be planarized by a planarizing process.

Subsequently, at least one first opening OP1, at least one second opening OP2, and the second slit SI2 may be formed by etching the second upper insulating layer 135 and the second stack structure ST2. The first opening OP1, the second opening OP2, and the second slit SI2 may be simultaneously formed by an etching process using a mask pattern (not illustrated) having opening regions corresponding to the first opening OP1, the second opening OP2, and the second slit SI2 as an etching barrier.

The mask pattern may be a photoresist pattern and may be removed after the first opening OP1, the second opening OP2, and the second slit SI2 are formed. Each of the first opening OP1, the second opening OP2, and the second slit SI2 may expose the sacrificial layers 123.

The second slit SI2 may be formed by etching a first region of the second stack structure ST2 which overlaps the first slit SI1. At least one first opening OP1 and at least one second opening OP2 may be formed at second regions of the second stack structure ST2, respectively, which overlap the first stack structures ST1. The first opening OP1, the second opening OP2, and the second slit SI2 may have the layout described above with reference to FIG. 3B. The second opening OP2 may have one layout among the layouts described above with reference to FIGS. 8A and 8B.

Referring to FIG. 14B, interlayer spaces 141 may be opened by removing the sacrificial layers 123 shown in FIG. 14A through the first opening OP1, the second opening OP2, and the second slit SI2. The interlayer spaces 141 may be formed at the second regions of the second stack structures ST2, respectively, which overlap the first stack structures ST1, and may be defined between the second interlayer insulating layers 121 neighboring each other in the first direction Z.

Referring to FIG. 14C, the interlayer spaces 141 shown in FIG. 14B may be filled with a conductive material 151 through the first opening OP1, the second opening OP2, and the second slit SI2.

The conductive material 151 may have a thickness to open a central region of each of the first opening OP1 and the second slit SI2 and to completely fill the second opening OP2. According to an embodiment, as described above with reference to FIG. 3B, the second opening OP2 may have a smaller width than the first opening OP1, and the first opening OP1 may have a smaller width than the second slit SI2. Accordingly, when the conductive material 151 is deposited, the second opening OP2 having a relatively small width may be completely filled and the central region of each of the first opening OP1 and the second slit SI2 which has a relatively large width may be opened by controlling deposition thickness.

The conductive material 151 may be formed by using an Atomic layer deposition (ALD) method, a chemical vapor deposition (CVD) method, and the like. The conductive material 151 may include metal for low resistance wiring. For example, the conductive material 151 may include at least one of a metal layer and a metal silicide layer. For example, a metal layer may include tungsten, cobalt, ruthenium, and the like. A metal silicide layer may include tungsten silicide, cobalt silicide, and the like. However, the embodiment is not limited thereto, and a metal layer and a metal silicide layer may include various metals.

Although not illustrated in FIG. 14C, a barrier thin film may be further formed before forming the conductive material 151. The barrier thin film may prevent metal from diffusing from the conductive material 151 into the second interlayer insulating layers 121 and the gate insulating layer GI. The barrier thin film may include a metal nitride layer. For example, a metal nitride layer may include a titanium nitride, a tungsten nitride, or a tantalum nitride.

As described above with reference to FIGS. 14A to 14C, according to an embodiment, the sacrificial layers of the second stack structures may be replaced with the conductive material 151 through the second slit SI2, the first opening OP1, and the second opening OP2. Since a pattern obstructing inflow of the conductive material 151 is not present at both sides of the second slit SI2, and the first opening OP1 and the second opening OP2 may serve as inlets of the conductive material 151, the sacrificial layers between the second channel structures CH2 may be easily replaced with the conductive material 151.

Referring to FIG. 14D, the conductive material 151 shown in FIG. 14C may be etched to expose bottom surfaces of the second slit SI2 and the first opening OP1. Thereby, the conductive material 151 may be divided into second conductive patterns 151P1, 151P2, and 151P3. The second conductive patterns 151P1, 151P2, and 151P3 may be separated from each other by the first opening OP1 or the second slit SI2.

Each of the second conductive patterns 151P1, 151P2, and 151P3 may include the electrode portions EP, the connecting portion CN, and the first spacer electrode SP1, or include the electrode portions EP, the connecting portion CN, and the second spacer electrode SP2 as described above in FIG. 4A. The second interlayer insulating layers 121 may be disposed between the electrode portions EP neighboring each other in the first direction Z. Each of the connecting portion CN, the first spacer electrode SP1, and the second spacer electrode SP2 may extend along sidewalls of the corresponding electrode portions EP and sidewalls of the corresponding second interlayer insulating layers 121.

A portion of the conductive material 151 completely filling the second opening OP2 shown in FIG. 14C may be removed by a predetermined thickness by the etching process illustrated in FIG. 14D, and the rest of the conductive material 151 may remain as the connecting portion CN in the second opening OP2. The connecting portion CN may couple the electrode portions EP stacked on each other in the first direction Z. The upper end of the second opening OP2 may be opened by an etching process. According to an embodiment, since the electrode portions EP disposed to be spaced apart from each other in the first direction Z and the connecting portion CN coupling the electrode portions EP are simultaneously formed, a manufacturing process of a semiconductor device may be simplified.

A portion of the conductive material 151 formed along a surface of each of the first opening OP1 and the second slit SI2 shown in FIG. 14C may be removed by the etching process shown in FIG. 14D. The conductive material may remain as the first spacer electrode SP1 on a sidewall of the first opening OP1 and remain as the second spacer electrode SP2 on a sidewall of the second slit SI2. The first spacer electrode SP1 and the second spacer electrode SP2 may couple the corresponding electrode portions EP, respectively.

The first and second spacer electrodes SP1 and SP2 may remain lower than the connecting portion CN by the etching process shown in FIG. 14D.

Referring to FIG. 14E, a third upper insulating layer 153 may be formed to completely fill the first opening OP1. The third upper insulating layer 153 may include various insulating materials, for example, an oxide layer.

The third upper insulating layer 153 may be conformally deposited on a surface of the second slit SI2 having a greater width than the first opening OP1. The third upper insulating layer 153 may completely fill the second opening OP2 having a smaller width than the first opening OP1. The third upper insulating layer 153 may extend to cover the second upper insulating layer 135.

Referring to FIG. 14F, a portion of the third upper insulating layer 153 shown in FIG. 14E may be removed by an etching process such as an etch back process. Thereby, the third upper insulating layer 153 may be divided into a plurality of patterns 153A, 153B, and 153C. When the third upper insulating layer 153 is etched, the second interlayer insulating layer 121 on the first vertical conductive pattern 113 may be etched and the second slit SI2 may extend to expose the first vertical conductive pattern 113.

The plurality of patterns 153A, 153B, and 153C may include the separation insulating layer 153A, the second slit insulating layer 153B, and the upper insulating pattern 153C. The separation insulating layer 153A may fill a space between the second conductive patterns 151P1 and 151P2 in the first opening OP1. The second silt insulating layer 153B may be formed on the sidewall of the second slit SI2 and cover a sidewall of each of the second conductive patterns 151P2 and 151P3. The upper insulating pattern 153C may fill an upper end of the second opening OP2.

Referring to FIG. 14G, a second vertical conductive pattern 155 filling the second slit SI2 may be formed on the second slit insulating layer 153B. The second vertical conductive pattern 155 may include various conductive materials. The second vertical conductive pattern 155 may include metal to improve resistance. The second vertical conductive pattern 155 may be coupled to the first vertical conductive pattern 113.

Referring to FIG. 14H, first and second contact plugs 161A and 161B passing through at least one of the second upper insulating layer 135, the second interlayer insulating layer 121, and the first upper insulating layer 105 may be formed.

Each of the first conductive patterns 103 may be coupled to the corresponding first contact plug 161A. The first contact plug 161A may pass through the second upper insulating layer 135 and the first upper insulating layer 105 to be coupled to the corresponding first conductive pattern 103. The first contact plug 161A may be coupled to an end portion of the corresponding first conductive pattern 103 which is exposed through the stepped structure formed by the first conductive patterns 103. The first contact plug 161A may be coupled to the pad portion 103P of the corresponding first conductive pattern 103.

Each of the second conductive patterns 151P1, 151P2, and 151P3 may be coupled to the corresponding second contact plug 161B. The second contact plug 161B may pass through the second upper insulating layer 135 and the second interlayer insulating layer 121 to be coupled to the corresponding second conductive pattern (for example, 151P2).

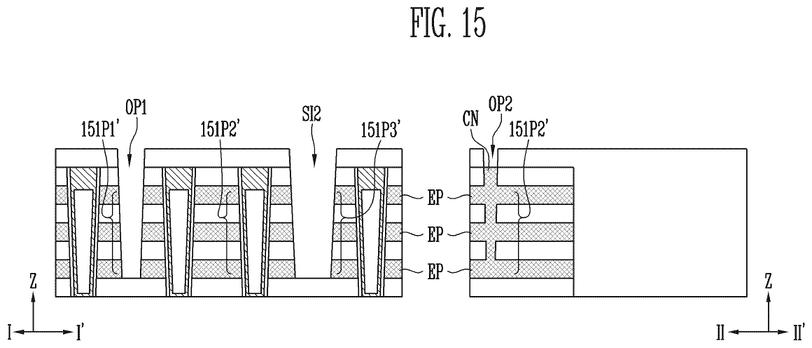

FIG. 15 is a cross-sectional diagram illustrating an example of a variation of a step of separating second conductive patterns from each other. FIG. 15 illustrates an example of a variation of a subsequent process after forming the conductive material described with reference to FIG. 14C.

Referring to FIG. 15, when the conductive material 151 shown in FIG. 14C is etched to expose the bottom surfaces of the second slit SI2 and the first opening OP1, the upper end of the second opening OP2 may be opened and the sidewall of each of the first opening OP1 and the second slit SI2 may be exposed. Thereby, the conductive material 151 may be divided into second conductive patterns 151P1′, 151P2′, and 151P3′ by the first opening OP1 and the second slit SI2.

Each of the second conductive patterns 151P1′, 151P2′, and 151P3′ may include the electrode portions EP and the connecting portion CN as described above with reference to FIG. 4B.

A portion of the conductive material 151 completely filling the second opening OP2 shown in FIG. 14C may be removed by a predetermined thickness by the etching process illustrated in FIG. 15, and the rest of the conductive material 151 may remain as the connecting portion CN in the second opening OP2. The connecting portion CN may couple the electrode portions EP stacked in the first direction Z.

After the process shown in FIG. 15, the processes described above with reference to FIGS. 14E to 14H may be successively performed.

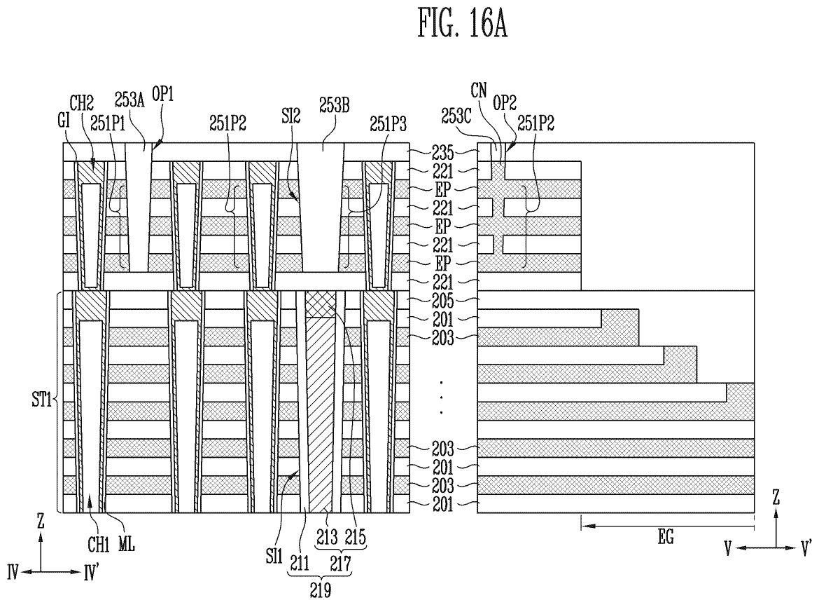

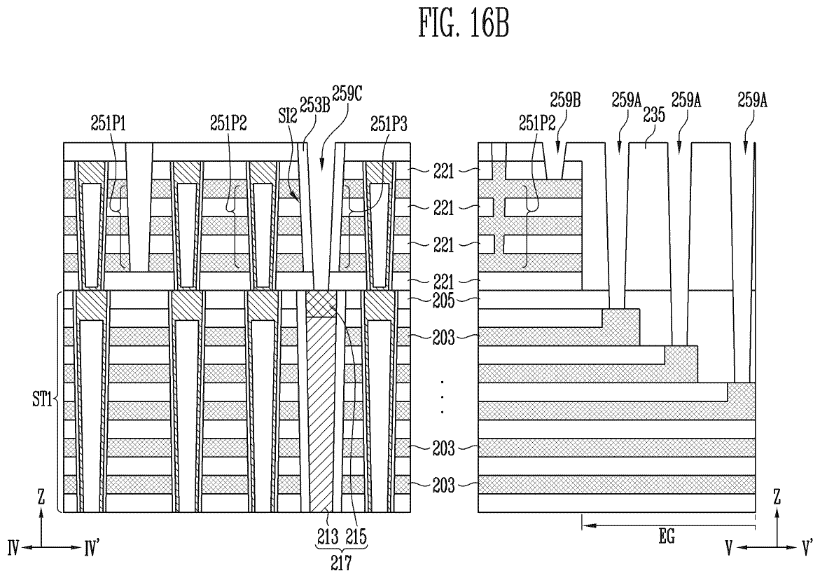

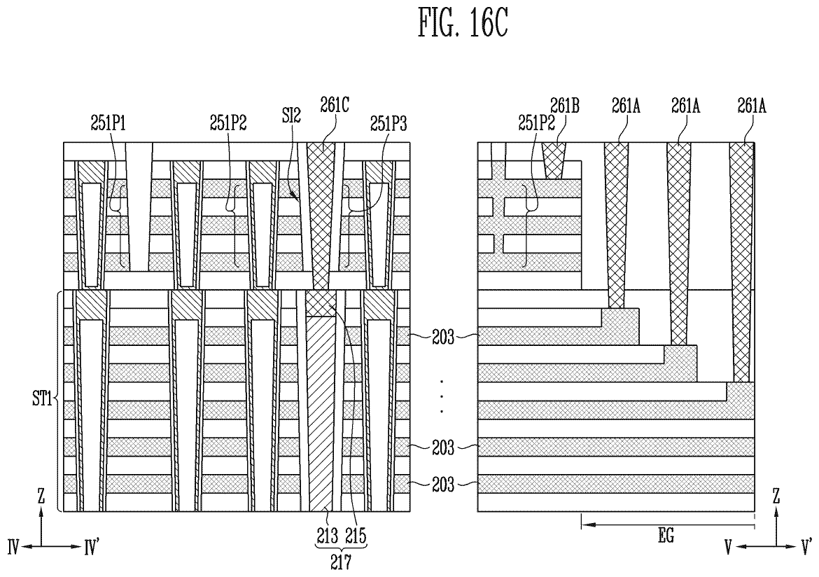

FIGS. 16A to 16C are cross-sectional diagrams illustrating a manufacturing method of a semiconductor device according to an embodiment. FIGS. 16A to 16C illustrate processes used for forming the semiconductor device shown in FIG. 5. Each of FIGS. 16A to 16C may correspond to the cross-sectional diagrams taken along lines IV-IV′ and V-V′ shown in FIG. 5.

Referring to FIG. 16A, the first stack structures ST1 penetrated by the first channel structures CH1 and separated from each other by the first slit SI1 may be formed using a series of processes shown in FIG. 10. Each of the first stack structures ST1 may have the same structure as described above with reference to FIG. 11. In other words, each of the first stack structures ST1 may include first interlayer insulating layers 201 and first conductive patterns 203 which are alternately stacked on each other in the first direction Z and which enclose the first channel structures CH1. The first conductive patterns 203 may be stacked to have a stepped shape at the end portion EG of each of the first stack structures ST1. The stepped end portions of the first conductive patterns 203 may be covered by a first upper insulating layer 205 extending towards the end portion EG of the first stack structure ST1. The outer wall of each of the first channel structures CH1 may be surrounded with the multilayer ML as described above with reference to FIG. 11.

The first slit SI1 may be filled with a first vertical structure 219 during step P9 shown in FIG. 10. Step P9 may include forming a first slit insulating layer 211 and forming a first vertical conductive pattern 217. Forming the first slit insulating layer 211 may be performed by using the processes described above with reference to FIG. 11.

The first vertical conductive pattern 217 may at least include a doped semiconductor layer. According to an embodiment, forming the first vertical conductive pattern 217 may include filling a central region of the first slit SI1 which is opened by the first slit insulating layer 211 with a doped semiconductor layer 213, opening an upper end of the first slit SI1 by removing a portion of the doped semiconductor layer 213, and filling the open upper end of the first slit SI1 with an upper conductive layer 215 containing metal. When the first vertical conductive pattern 217 serves as a source pick-up plug coupled to a source region, the doped semiconductor layer 213 may include an n-type impurity. The upper conductive layer 215 containing metal may include at least one of a metal silicide layer, a metal layer, and a metal nitride layer. The upper conductive layer 215 may include metal such as tungsten, cobalt, ruthenium, for low resistance wiring.

After forming the first stack structures ST1 and the first vertical structure 219, second conductive patterns 251P1, 251P2, and 251P3 separated from each other by the first opening OP1 or the second slit SI2 may be formed. The second conductive patterns 251P1, 251P2, and 251P3 may be formed by using the processes described above with reference to FIGS. 12A, 12B, 13A, 13B, and 14A to 14D or the processes described above with reference to FIG. 15.

Each of the second conductive patterns 251P1, 251P2, and 251P3 may expose the end portion EG of the first stack structure ST1. Each of the second conductive patterns 251P1, 251P2, and 251P3 may include the electrode portions EP and the connecting portion CN as described above with reference to FIG. 14D or 15. The electrode portions EP may be penetrated by the second channel structures CH2 coupled to the first channel structures CH1.

The second channel structures CH2 may be surrounded with second interlayer insulating layers 221 and the electrode portions EP which are alternately stacked on each other in the first direction Z. The outer wall of each of the second channel structures CH2 may be surrounded with the gate insulating layer GI. Each of the second conductive patterns 251P1, 251P2, and 251P3 may further include a first spacer electrode or a second spacer electrode as described above with reference to FIG. 14D.

The first opening OP1 and the second slit SI2 between the second conductive patterns 251P1, 251P2, and 251P3 which neighbor each other, and the upper end of the second opening OP2 which is opened above the connecting portion CN may be completely filled with a third upper insulating layer. Subsequently, a surface of the third upper insulating layer may be planarized. The third upper insulating layer may be divided into a separation insulating layer 253A filling the first opening OP1, a second slit insulating layer 253B filling the second slit SI2, and an upper insulating pattern 253C filling the upper end of the second opening OP2.

Referring to FIG. 16B, contact holes 259A, 259B, and 259C passing through at least one of the second slit insulating layer 253B, a second upper insulating layer 235 and the first upper insulating layer 205 may be formed. The contact holes 259A, 259B, and 259C may be divided into first to third contact holes.

The first contact hole 259A may pass through the second upper insulating layer 235 and the first upper insulating layer 205 to expose an end portion of the corresponding first conductive pattern 203. The first contact hole 259A may be disposed on the end portion EG of the first stack structure ST1.

The second contact hole 259B may pass through the second upper insulating layer 235 to expose the corresponding second conductive pattern (for example, 251P2). The second contact hole 259B may further pass through the second interlayer insulating layer 221.

The third contact hole 259C may pass through the second slit insulating layer 253B to expose the first vertical conductive pattern 217. The third contact hole 259C may further pass through the second interlayer insulating layer 221 which remains at a bottom surface of the second slit SI2.

The first, second, and third contact holes 259A, 259B, and 259C may be simultaneously formed by an etching process using a mask pattern (not illustrated) which has open regions that correspond to the first, second, and third contact holes 259A, 259B, and 259C as an etching barrier. The mask pattern may be a photoresist pattern and may be removed after the first, second, and third contact holes 259A, 259B, and 259C are formed.

Referring to FIG. 16C, after filling the first, second, and third contact holes 259A, 259B, and 259C which are shown in FIG. 16B with a conductive material, the conductive material may be etched to be divided into a plurality of patterns 261A, 261B, and 261C. The plurality of patterns 261A, 261B, and 261C may include the first contact plug 261A filling the first contact hole 259A shown in FIG. 16B, the second contact plug 261B filling the second contact hole 259B shown in FIG. 16B, and the second vertical conductive pattern 261C filling the third contact hole 259C shown in FIG. 16B.

A conductive material for the first and second contact plugs 261A and 261B, and the second vertical conductive pattern 261C may include metal to improve resistance. The second vertical conductive pattern 261C may be coupled to the upper conductive layer 215 of the first vertical conductive pattern 219.

Each of the first conductive patterns 203 may be coupled to the corresponding first contact plug 261A. Each of the second conductive patterns 251P1, 251P2, and 251P3 may be coupled to the corresponding second contact plug 261B.

The present disclosure may lower a level of difficulty of a manufacturing process of a semiconductor device by separately performing a process of forming first conductive patterns surrounding first channel structures and a process of forming second conductive patterns enclosing second channel structures.

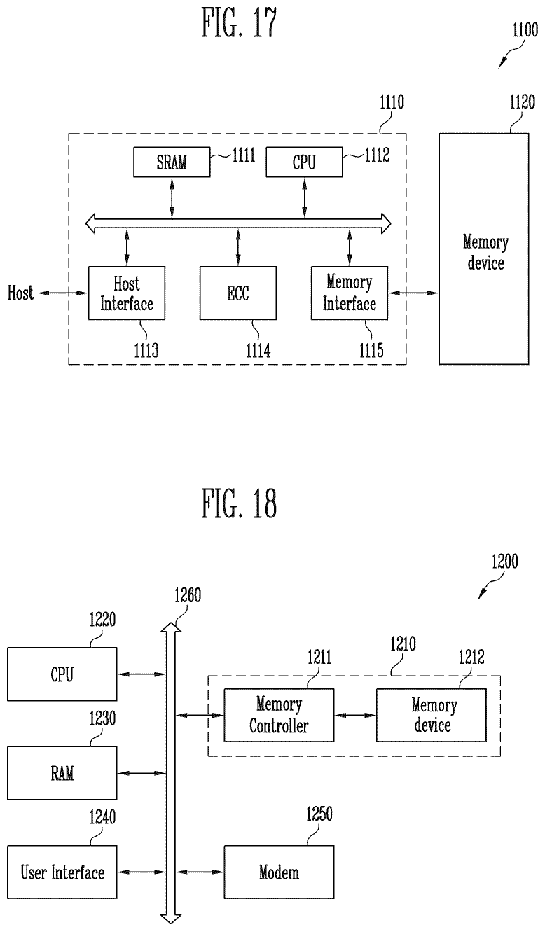

FIG. 17 is a block diagram illustrating a configuration of a memory system 1100 according to an embodiment.

Referring to FIG. 17, the memory system 1100 according to the embodiment may include a memory device 1120 and a memory controller 1110.

The memory device 1120 may be a multi-chip package formed of a plurality of flash memory chips. The memory device 1120 may include at least one of the first and second stack structures according to the embodiments described with reference to FIGS. 3A, 3B, 4A, 4B, 4C, 4D, 4E, 4F, 5, 6, 8A, and 8B or at least one of the three-dimensional semiconductor devices according to the embodiments described with reference to FIGS. 9A to 9D.

The memory controller 1110 may be configured to control the memory device 1120 and include a Static Random Access Memory (SRAM) 1111, a CPU 1112, a host interface 1113, an Error Correction Code circuit (ECC) 1114, and a memory interface 1115. The SRAM 1111 may serve as an operation memory of the CPU 1112, the CPU 1112 may perform overall control operations for data exchange of the memory controller 1110, and the host interface 1113 may include a data exchange protocol for a host connected with the memory system 1100. In addition, the ECC 1114 may detect and correct errors included in the data read from the memory device 1120, and the memory interface 1115 may perform interfacing with the memory device 1120. In addition, the memory controller 1110 may further include a Read Only Memory (ROM) for storing code data for interfacing with the host.

The above-described memory system 1100 may be a memory card or a Solid State Disk (SSD) equipped with the memory device 1120 and the memory controller 1110. For example, when the memory system 1100 is an SSD, the memory controller 1110 may communicate with an external device (e.g., a host) through one of various interface protocols including a Universal Serial Bus (USB), a MultiMedia Card (MMC), Peripheral Component Interconnection-Express (PCI-E), Serial Advanced Technology Attachment (SATA), Parallel Advanced Technology Attachment (PATA), a Small Computer System Interface (SCSI), an Enhanced Small Disk Interface (ESDI), and Integrated Drive Electronics (IDE).

FIG. 18 is a block diagram illustrating a configuration of a computing system 1200 according to an embodiment.

Referring to FIG. 18, the computing system 1200 according to an embodiment may include a CPU 1220, a Random Access Memory (RAM) 1230, a user interface 1240, a modem 1250, and a memory system 1210 which are electrically coupled to a system bus 1260. In addition, when the computing system 1200 is a mobile device, a battery for supplying an operating voltage to the computing system 1200 may be further included, and an application chipset, a camera image processor (CIS), a mobile DRAM, and the like may be further included. The memory system 1210 may include a memory controller 1211 and a memory device 1212. In some embodiments, the memory system 1210 may include the memory system 1100 according to the embodiments described above with reference to FIG. 17. The memory device 1212 may include at least one of the first and second stack structures according to the embodiments described with reference to FIGS. 3A, 3B, 4A, 4B, 4C, 4D, 4E, 4F, 5, 6, 8A, and 8B or at least one of the three-dimensional semiconductor devices according to the embodiments described with reference to FIGS. 9A to 9D.

So far as not being differently defined, all terms used herein including technical or scientific terminologies have meanings that they are commonly understood by those skilled in the art to which the present disclosure pertains. So far as not being clearly defined in this application, terms should not be understood in an ideally or excessively formal way.

What is claimed is:

1. A semiconductor device, comprising:
a peripheral circuit structure;
a memory cell array disposed over the peripheral circuit structure; and
a bonding structure disposed between the peripheral circuit structure and the memory cell array,
wherein the memory cell array comprising:
a first stack structure including first interlayer insulating layers and first conductive patterns disposed alternately with each other in a first direction over the bonding structure;
second conductive patterns separated from each other in a horizontal direction between the first stack structure and the bonding structure, each of the second conductive patterns comprising electrode portions spaced apart from in the first direction and a connection portion extending in the first direction to couple the electrode portions;
a vertical channel passing through the first stack structure and the electrode portions of each of the second conductive patterns; and
a separation insulating layer disposed between the second conductive patterns.

2. A semiconductor device of claim 1, wherein the first stack structure overlaps the separation insulating layer and the connection portion.

3. The semiconductor device of claim 1, wherein the bonding structure comprises:
a peripheral circuit side bonding insulating structure disposed between the peripheral circuit structure and the memory cell array;
a peripheral circuit side conductive bonding pattern inside the peripheral circuit-side bonding insulating structure;
a cell side bonding insulating structure disposed between the peripheral circuit side bonding insulating structure and the memory cell array; and
a cell side conductive bonding pattern bonded to the peripheral circuit side conductive bonding pattern and disposed inside the cell side bonding insulating structure.

4. The semiconductor device of claim 1, wherein memory cell array further comprises:
a bit line disposed between the bonding structure and each of the second conductive patterns and coupled to the vertical channel; and
a doped semiconductor structure disposed over a surface of the first stack structure facing a direction opposite to a direction toward the bit line.

5. The semiconductor device of claim 4, wherein the vertical channel includes a bottom surface being in contact with the doped semiconductor structure.

6. The semiconductor device of claim 4,
wherein the doped semiconductor structure includes a first doped semiconductor layer spaced apart from the first stack structure in the first direction, a second doped semiconductor layer between the first stack structure and the first doped semiconductor layer, and a third doped semiconductor layer between the first stack structure and the second doped semiconductor layer,
wherein the vertical channel passes through the third doped semiconductor layer and extends into the first doped semiconductor layer, and
wherein the vertical channel includes a sidewall being in contact with the second doped semiconductor layer.

7. The semiconductor device of claim 4,
wherein the doped semiconductor structure includes a groove into which the vertical channel is inserted,
wherein the vertical channel is in contact with a surface of the doped semiconductor structure adjacent to the groove.

8. The semiconductor device of claim 1, further comprising:
a first slit insulating layer covering a sidewall of the first stack structure; and
a second slit insulating layer over the first slit insulating layer.

9. The semiconductor device of claim 8, wherein one of the second conductive patterns is disposed between the second slit insulating layer and the separation insulating layer.

10. The semiconductor device of claim 8, wherein the connection portion of one of the second conductive patterns is disposed between the second slit insulating layer and the separation insulating layer.

11. The semiconductor device of claim 1, wherein the separation insulating layer is in contact with the electrode portions.

12. The semiconductor device of claim 1, wherein each of the second conductive patterns further comprises a spacer electrode extending along a sidewall of the separation insulating layer to connect the electrode portions.

13. A semiconductor device, comprising:
a peripheral circuit structure;
a first sub-memory cell array disposed over the peripheral circuit structure;
a second sub-memory cell array disposed over the first sub-memory cell array;
a first bonding structure disposed between the peripheral circuit structure and the first sub-memory cell array; and
a second bonding structure disposed between the first sub-memory cell array and the second sub-memory cell array,
wherein the first sub-memory cell array comprising:
a first type-first stack structure including first type-first interlayer insulating layers and first type-first conductive patterns disposed alternately with each other in a first direction over the first bonding structure;
first type-second conductive patterns separated from each other in a horizontal direction between the first type-first stack structure and the first bonding structure, each of the first type-second conductive patterns comprising first type-electrode portions spaced apart from in the first direction and a first type-connection portion extending in the first direction to couple the first type-electrode portions;
a first type-vertical channel passing through the first type-first stack structure and the first type-electrode portions of each of the first type-second conductive patterns; and
a first type-separation insulating layer disposed between the first type-second conductive patterns.

14. A semiconductor device of claim 13, wherein the first type-first stack structure overlaps the first type-separation insulating layer and the first type-connection portion.

15. The semiconductor device of claim 13, wherein the first bonding structure comprises:
a peripheral circuit side bonding insulating structure disposed between the peripheral circuit structure and the first sub-memory cell array;
a peripheral circuit side conductive bonding pattern inside the peripheral circuit side bonding insulating structure;
a cell side bonding insulating structure disposed between the peripheral circuit side bonding insulating structure and the first sub-memory cell array; and
a cell side conductive bonding pattern bonded to the peripheral circuit side conductive bonding pattern and disposed inside the cell side bonding insulating structure.

16. The semiconductor device of claim 13, wherein first sub-memory cell array further comprises:
a first bit line disposed between the first bonding structure and each of the first type-second conductive patterns and coupled to the first-type vertical channel; and
a first doped semiconductor structure disposed over a surface of the first type-first stack structure facing a direction opposite to a direction toward the first bit line.

17. The semiconductor device of claim 16, wherein the second sub-memory cell array comprises:
a second doped semiconductor structure over the second bonding structure;
a second type-first stack structure including second type-first interlayer insulating layers and second type-first conductive patterns disposed alternately with each other in the first direction over the second doped semiconductor structure;
second type-second conductive patterns separated from each other in the horizontal direction between the second type-first stack structure and the second doped semiconductor structure, each of the second type-second conductive patterns comprising second type-electrode portions spaced apart from in the first direction and a second type-connection portion extending in the first direction to couple the second type-electrode portions;
a second type-vertical channel passing through the second type-first stack structure and the second type-electrode portions of each of the second type-second conductive patterns; and
a second type-separation insulating layer disposed between the second type-second conductive patterns.

18. The semiconductor device of claim 17, wherein the second bonding structure comprises a first bonding layer and a second bonding layer bonded to each other between the first doped semiconductor structure and the second doped semiconductor structure.

19. The semiconductor device of claim 16, wherein the second sub-memory cell array comprises:
a second type-first stack structure including second type-first interlayer insulating layers and second type-first conductive patterns disposed alternately with each other in the first direction over the second bonding structure;
second type-second conductive patterns separated from each other in the horizontal direction between the second type-first stack structure and the second bonding structure, each of the second type-second conductive patterns comprising second type-electrode portions spaced apart from in the first direction and a second type-connection portion extending in the first direction to couple the second type-electrode portions;
a second type-vertical channel passing through the second type-first stack structure and the second type-electrode portions of each of the second type-second conductive patterns;
a second type-separation insulating layer disposed between the second type-second conductive patterns; and
a second bit line between the second type-vertical channel and the second bonding structure.

20. The semiconductor device of claim 19, wherein the second bonding structure comprises:
a first cell side bonding insulating structure disposed between the first sub-memory cell array and a second sub-memory cell array;
a first cell side conductive bonding pattern inside the first cell side bonding insulating structure;
a second cell side bonding insulating structure disposed between the first cell side bonding insulating structure and the second sub-memory cell array; and
a second cell side conductive bonding pattern bonded to the first cell side conductive bonding pattern and disposed inside the second cell side bonding insulating structure.
